(19) United States
(12) Patent Application Publication
(10) Pub. No.: US 2026/0324376 A1
(43) Pub. Date: Oct. 15, 2026

(54) SHALLOW-TRENCH ISOLATION PROTECTION STRUCTURE FOR NANOSTRUCTURE FIELD-EFFECT TRANSISTOR DEVICE AND METHODS OF FORMING

(71) Applicant: Taiwan Semiconductor Manufacturing Co., Ltd., Hsinchu (TW)

(72) Inventors: Wan-Yi Kao, Baoshan Township (TW); ChunYao Wang, Zhubei City (TW); Tze-Liang Lee, Hsinchu (TW)

(21) Appl. No.: 19/717,352

(22) Filed: Jun. 23, 2026

Related U.S. Application Data
(63) Continuation of application No. 18/883,661, filed on Sep. 12, 2024.
(60) Provisional application No. 63/655,665, filed on Jun. 4, 2024.

(51) Int. Cl. H10W 10/00; H10D 30/01; H10D 30/43; H10D 30/67; H10D 62/10; H10D 64/01; H10P 14/60; H10P 14/692; H10P 14/694; H10W 10/17

(52) U.S. Cl. CPC H10W 10/014; H10D 30/014; H10D 30/43; H10D 30/6735; H10D 30/6757; H10D 62/121; H10D 64/017; H10D 64/018; H10P 14/6316; H10P 14/6339; H10P 14/69215; H10P 14/69433; H10W 10/17

(57) ABSTRACT

A method of forming a semiconductor device includes: forming a fin structure protruding above a substrate, the fin structure including a fin and alternating layers of a first semiconductor material and a second semiconductor material over the fin; forming shallow trench isolation (STI) regions on opposing sides of the fin structure; forming an STI protection structure on upper surfaces of the STI regions; forming a dummy gate structure over the fin structure; forming source/drain openings in the fin structure to expose the first and second semiconductor materials; replacing the first semiconductor material disposed under the dummy gate structure with a sacrificial material; after the replacing, forming source/drain regions in the source/drain openings; after forming the source/drain regions, removing the sacrificial material and replacing the dummy gate structure with a replacement gate structure.

### PRIORITY CLAIM AND CROSS-REFERENCE

This application is a continuation of U.S. Patent Application No. 18/883,661, filed Sep. 12, 2024 and entitled “Shallow-Trench Isolation Protection Structure for Nanostructure Field-Effect Transistor Device and Methods of Forming,” which claims priority to U.S. Provisional Application No. 63/655,665, filed Jun. 4, 2024 and entitled “Method for Forming a Semiconductor Structure,” which applications are incorporated herein by reference.

### BACKGROUND

Semiconductor devices are used in a variety of electronic applications, such as, for example, personal computers, cell phones, digital cameras, and other electronic equipment. Semiconductor devices are typically fabricated by depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (NSFET) device in a three-dimensional view, in accordance with some embodiments.

FIGS. 2, 3A, 3B, 4A, 4B, 5A, 5B, 6A, 6B, 7A, 7B, 8A, 8B, 9A, 9B, 10A, 10B, 11A, 11B, 12A, 12B, 12C, 13A, 13B, 13C, 14A, 14B, 14C, 15A, 15B, 15C, 16A, 16B, 16C, 17A, 17B, 17C, 18A, 18B, 18C, 19A, 19B, 20A, 20B, 21A, and 21B,are cross-sectional views of a portion of a nanostructure field-effect transistor (NSFET) device at various stages of manufacturing, in accordance with an embodiment.

FIGS. 22A and 22B together illustrate a flow chart of a method of forming a semiconductor device, in some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

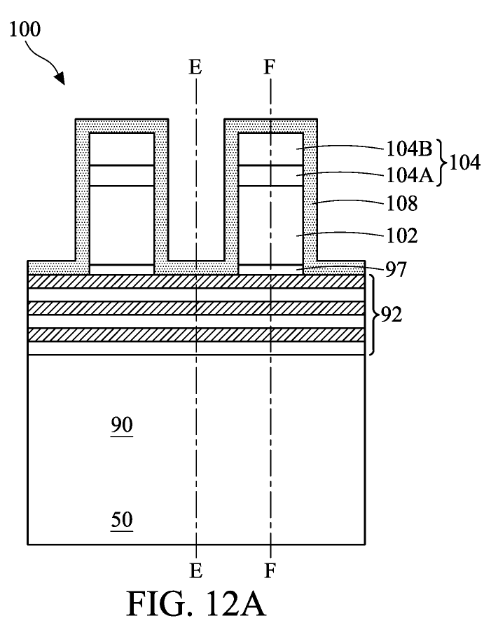

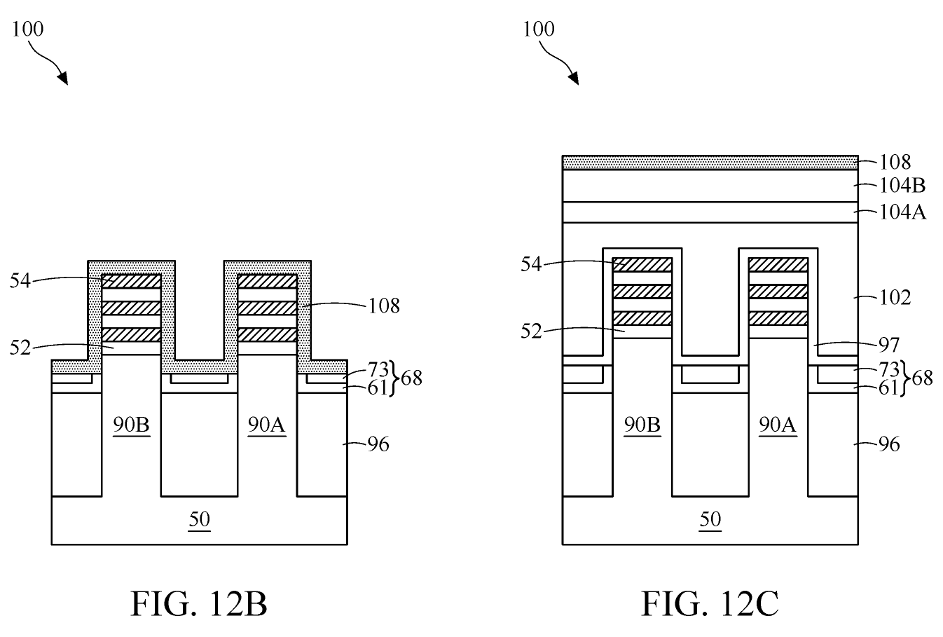

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Throughout the discussion herein, unless otherwise specified, the same or similar reference numeral in different figures refer to the same or similar component formed by a same or similar formation process using a same or similar material(s). In addition, figures with the same numeral but different alphabets (e.g., FIGS. 12A – 12C) illustrate different views of the device at the same stage of processing.

Disclosed embodiment relates to a shallow trench isolation (STI) protection structure formed on the STI regions of an NSFET device. The STI protection structure protects the STI regions (e.g., portions directly under dummy gate structure) during the selective etching of a disposable material used in a disposable oxide interposer (DOI) process for forming the NSFET device. In some embodiments, a fin structure is formed protruding above a substrate and STI regions on opposing sides of the fin structure. The fin structure includes a fin and a layer stack over the fin, where the layer stack comprises alternating layers of a first semiconductor material and a second semiconductor material. Next, an STI protection structure is formed on the upper surfaces of the STI regions. In an embodiment, the STI protection structure comprises a liner layer and a hard mask layer over the liner layer. A disclosed plasma-enhanced chemical vapor deposition (PECVD) process forms the hard mask layer with a non-uniform thickness to advantageously form the STI protection structure. Next, a dummy gate structure is formed over the fin structure, and source/drain openings are formed on opposing sides of the dummy gate structure. Next, the first semiconductor material in the layer stack and under the dummy gate structure is replaced by a sacrificial material (e.g., an oxide). Source/drain regions are formed next in the source/drain openings. Next, the dummy gate structure is replaced by a replacement gate structure in a replacement gate process. During the selective etching process used for removing the sacrificial material to release the second semiconductor material to form the nanostructures, the STI protection structure protects portions of the STI regions disposed directly under the dummy gate structure from the selective etching process, and therefore, prevents or reduces loss of the STI regions due to the selective etching process. Advantages of using the STI protection structure include reduced parasitic capacitance of the replacement gate structure, improved device performance, and improved production yield.

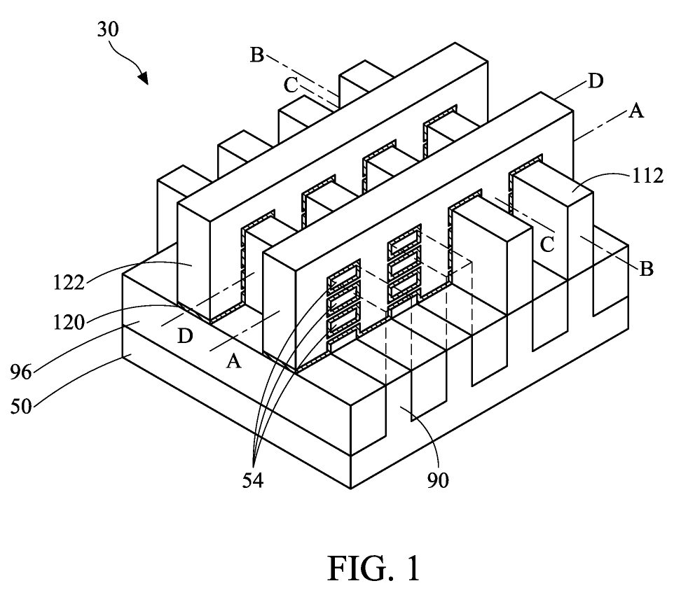

FIG. 1 illustrates an example of a nanostructure field-effect transistor (NSFET) device 30 in a three-dimensional view, in accordance with some embodiments. The NSFET device 30 comprises semiconductor fins 90 (also referred to as fins) protruding above a substrate 50. Gate electrodes 122 (e.g., metal gates) are disposed over the fins, and source/drain regions 112 are formed on opposing sides of the gate electrodes 122. A plurality of nanostructures 54 (e.g., nanowires, or nanosheets) are formed over the fins 90 and between source/drain regions 112. Isolation regions 96 are formed on opposing sides of the fins 90. A gate dielectric layer 120 is formed around the nanostructures 54. Gate electrodes 122 are over and around the gate dielectric layer 120.

FIG. 1 further illustrates reference cross-sections that are used in later figures. Cross-section A-A is along a longitudinal axis of the gate electrode 122 and in a direction, for example, perpendicular to the direction of current flow between the source/drain regions 112 of the NSFET device 30. Cross-section B-B is perpendicular to cross-section A-A and is along a longitudinal axis of the fin 90 and in a direction of, for example, a current flow between the source/drain regions 112 of the NSFET device. Cross-section C-C is parallel to cross-section B-B and between two neighboring fins 90. Cross-section D-D is parallel to cross-section A-A and extends through source/drain regions 112 of the NSFET device. Subsequent figures may refer to these reference cross-sections for clarity.

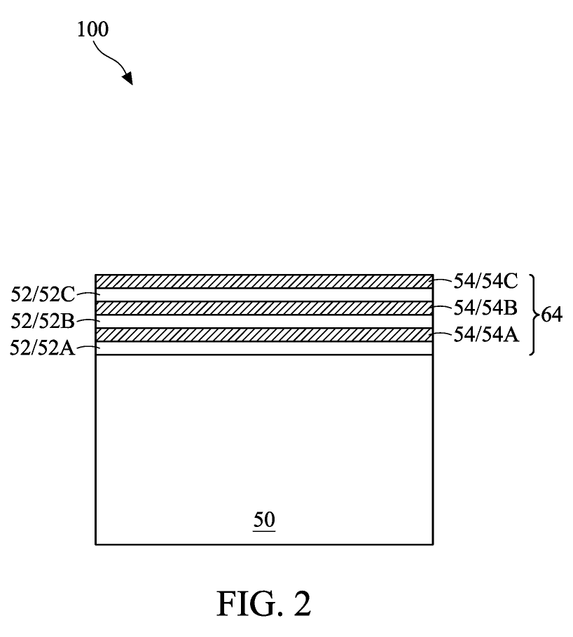

FIGS. 2, 3A, 3B, 4A, 4B, 5A, 5B, 6A, 6B, 7A, 7B, 8A, 8B, 9A, 9B, 10A, 10B, 11A, 11B, 12A, 12B, 12C, 13A, 13B, 13C, 14A, 14B, 14C, 15A, 15B, 15C, 16A, 16B, 16C, 17A, 17B, 17C, 18A, 18B, 18C, 19A, 19B, 20A, 20B, 21A, and 21B,are cross-sectional views of a portion of a nanostructure field-effect transistor (NSFET) device 100 at various stages of manufacturing, in accordance with an embodiment.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon substrate or a glass substrate. Other substrates, such as a multi-layered or gradient substrate may also be used. In some embodiments, the semiconductor material of the substrate 50 includes silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

A multi-layer stack 64 is formed on the substrate 50. The multi-layer stack 64 includes alternating layers of a first semiconductor material 52 and a second semiconductor material 54. In FIG. 2, layers formed by the first semiconductor material 52 are labeled as 52A, 52B, and 52C, and layers formed by the second semiconductor material 54 are labeled as 54A, 54B, and 54C. The number of layers formed by the first and the second semiconductor materials illustrated in FIG. 2 are merely non-limiting examples. Other numbers of layers are also possible and are fully intended to be included within the scope of the present disclosure.

In some embodiments, the first semiconductor material 52 is a first type of epitaxial material, such as silicon germanium (SiₓGe₁₋ₓ, where x can be in the range of 0 to 1), and the second semiconductor material 54 is a second type of epitaxial material, such as silicon. The multi-layer stack 64 (which may also be referred to as an epitaxial material stack) will be patterned to form channel regions of an NSFET in subsequent processing. In particular, the multi-layer stack 64 will be patterned and etched to form nanostructures (e.g., nanosheets or nanowires), with the channel regions of the resulting NSFET including multiple horizontally extending nanostructures.

The multi-layer stack 64 may be formed by an epitaxial growth process, which may be performed in a growth chamber. During the epitaxial growth process, the growth chamber is cyclically exposed to a first set of precursors for selectively growing the first semiconductor material 52, and then exposed to a second set of precursors for selectively growing the second semiconductor material 54, in some embodiments. The first set of precursors includes precursors for the first semiconductor material (e.g., silicon germanium), and the second set of precursors includes precursors for the second semiconductor material (e.g., silicon). In some embodiments, the first set of precursors includes a silicon precursor (e.g., silane) and a germanium precursor (e.g., a germane), and the second set of precursors includes the silicon precursor but omits the germanium precursor. The epitaxial growth process may thus include continuously enabling a flow of the silicon precursor to the growth chamber, and then cyclically: (1) enabling a flow of the germanium precursor to the growth chamber when growing the first semiconductor material 52; and (2) disabling the flow of the germanium precursor to the growth chamber when growing the second semiconductor material 54. The cyclical exposure may be repeated until a target number of layers is formed.

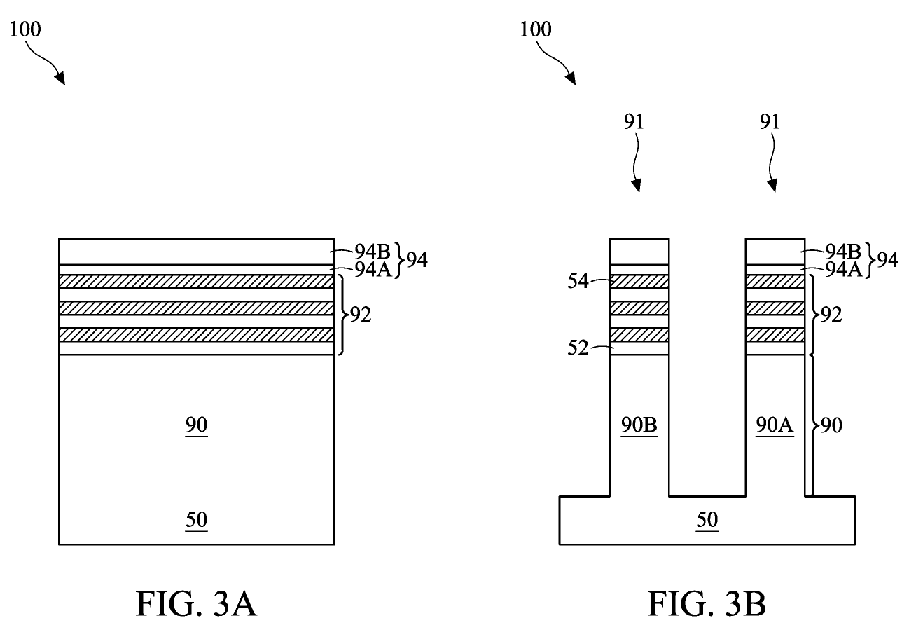

FIGS. 3A, 3B, 4A, 4B, 5A, 5B, 6A, 6B, 7A, 7B, 8A, 8B, 9A, 9B, 10A, 10B, 11A, 11B, 12A, 12B, 12C, 13A, 13B, 13C, 14A, 14B, 14C, 15A, 15B, 15C, 16A, 16B, 16C, 17A, 17B, 17C, 18A, 18B, 18C, 19A, 19B, 20A, 20B, 21A, and 21B, are cross-sectional views of the NSFET device 100 at subsequent stages of manufacturing, in accordance with an embodiment. FIGS. 3A, 4A, 5A, 6A, 7A, 8A, 9A, 10A, 11A, 12A, 13A, 14A, 15A, 16A, 17A, 18A, 19A, 20A, 21A. and 22A,are cross-sectional views along cross-section B-B in FIG. 1. FIGS. 3B, 4B, 5B, 6B, 7B, 8B, 9B, 10B, 11B, 12C, 13C, 14C, 15C, 16C, 17C, 18C, 19B, 20B, and 21B, are cross-sectional views along cross-section A-A in FIG. 1. FIGS. 12B, 13B, 14B, 15B, 16B, 17B, and 18B,are cross-sectional views along cross-section D-D in FIG. 1. The number of fins and the number of gate structures illustrated in the figures are merely non-limiting examples, it should be appreciated that other numbers of fins and other numbers of gate structures may also be formed.

In FIG. 3A and 3B, fin structures 91 are formed protruding above the substrate 50. Each of the fin structures 91 includes a semiconductor fin 90 (also referred to as a fin) and a layer stack 92 overlying the semiconductor fin 90. The layer stack 92 and the semiconductor fin 90 may be formed by etching trenches in the multi-layer stack 64 and the substrate 50, respectively. The layer stack 92 and the semiconductor fin 90 may be formed by a same etching process.

The fin structures 91 may be patterned by any suitable method. For example, the fin structures 91 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern, e.g., the fin structures 91.

In some embodiments, the remaining spacers are used to pattern a mask 94, which is then used to pattern the fin structures 91. The mask 94 may be a single layer mask, or may be a multilayer mask such as a multilayer mask that includes a first mask layer 94A and a second mask layer 94B. The first mask layer 94A and second mask layer 94B may each be formed from a dielectric material such as silicon oxide, silicon nitride, a combination thereof, or the like, and may be deposited or thermally grown according to suitable techniques. The first mask layer 94A and second mask layer 94B are different materials having a high etching selectivity. For example, the first mask layer 94A may be silicon oxide, and the second mask layer 94B may be silicon nitride. The mask 94 may be formed by patterning the first mask layer 94A and the second mask layer 94B using any acceptable etching process. The mask 94 may then be used as an etching mask to etch the substrate 50 and the multi-layer stack 64. The etching may be any acceptable etching process, such as a reactive ion etch (RIE), neutral beam etch (NBE), the like, or a combination thereof. The etching is an anisotropic etching process, in some embodiments. After the etching process, the patterned multi-layer stack 64 forms the layer stack 92, and the patterned portion of the substrate 50 forms the fin 90 (e.g., 90A or 90B), as illustrated in FIG. 3A and 3B. The remaining (e.g., un-patterned) portion of the substrate 50 is referred to as the substrate 50 in FIGS. 3A and 3B and subsequent figures. Therefore, in the illustrated embodiment, the layer stack 92 also includes alternating layers of the first semiconductor material 52 and the second semiconductor material 54. The fin 90 is formed of a same material as the substrate 50. In the example of FIGS. 3A and 3B, fins 90A and 90B are formed to extend parallel to each other.

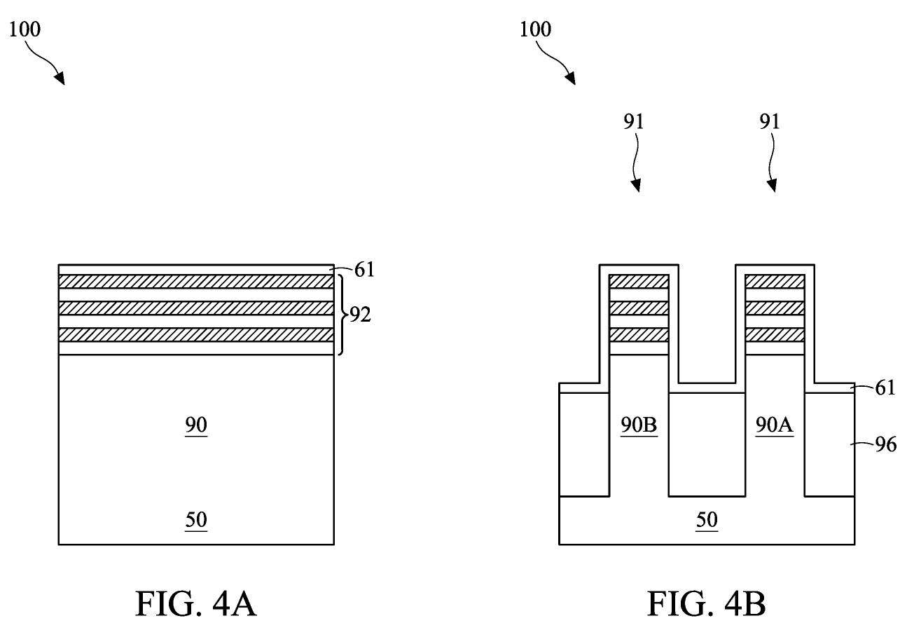

Next, in FIGS. 4A and 4B, shallow trench isolation (STI) regions 96 are formed over the substrate 50 and on opposing sides of the fin structures 91. As an example to form the STI regions 96, an insulation material may be formed over the substrate 50. The insulation material may be an oxide such as silicon oxide, a nitride, the like, or a combination thereof, and may be formed by a high-density plasma chemical vapor deposition (HDP-CVD), a flowable CVD (FCVD) (e.g., a CVD-based material deposition in a remote plasma system and post curing to make it convert to another material, such as an oxide), the like, or a combination thereof. Other insulation materials formed by any acceptable process may be used. In the illustrated embodiment, the insulation material is silicon oxide formed by an FCVD process. An anneal process may be performed after the insulation material is formed.

In some embodiments, the insulation material is formed such that excess insulation material covers the fin structures 91. In some embodiments, a liner is first formed along surfaces of the substrate 50 and fin structures 91, and a fill material, such as those discussed above is formed over the liner. In some embodiments, the liner is omitted.

Next, a removal process is applied to the insulation material to remove excess insulation material disposed over the fin structures 91. In some embodiments, a planarization process such as a chemical mechanical polish (CMP), an etch back process, combinations thereof, or the like, may be utilized. The planarization process exposes the layer stacks 92 such that top surfaces of the layer stacks 92 and the insulation material are level after the planarization process is complete. Next, the insulation material is recessed to form the STI regions 96. The insulation material is recessed such that the layer stacks 92 protrude from between neighboring STI regions 96. Top portions of the semiconductor fins 90 may also protrude from between neighboring STI regions 96. Further, the top surfaces of the STI regions 96 may have a flat surface as illustrated, a convex surface, a concave surface (such as dishing), or a combination thereof. The top surfaces of the STI regions 96 may be formed flat, convex, and/or concave by an appropriate etch. The STI regions 96 may be recessed using an acceptable etching process, such as one that is selective to the material of the insulation material (e.g., etches the material of the insulation material at a faster rate than the material of the fin 90 and the layer stack 92). For example, a chemical oxide removal with a suitable etchant such as dilute hydrofluoric (dHF) acid may be used.

Still referring to FIGS. 4A and 4B, a liner layer 61 is formed over the layer stacks 92 and over the STI regions 96. The liner layer 61 may be a suitable dielectric material such as silicon oxide, and may be formed using a suitable deposition method such as CVD, atomic layer deposition (ALD), or the like. The liner layer 61 protects the layer stacks 92 from damage by subsequent etching process(es) used to form an STI protection structure 68, in some embodiments. The liner layer 61 may also be referred to as an oxide liner layer. Besides silicon oxide, other suitable material, such as a dielectric material that provides high etching selectivity from the layer stack 92 and the subsequently formed hard mask layer 73 may also be used. In the illustrated embodiments, the liner layer 61 has a substantially uniform thickness. For example, the horizontal portions of the liner layer 61 (e.g., portions along the top surfaces of the fin structures 91 or along the upper surfaces of the STI regions 96) has a first thickness, the vertical portions of the liner layer 61 (e.g., portions along the sidewalls of the fin structures 91) has a second thickness, and the first thickness is within about 10% (e.g., between 90% and 110%, or between 95% and 105%) of the second thickness. The liner layer 61 may have a thickness (e.g., an average thickness) between about 2 nm and about 4 nm, such as 3 nm, as an example.

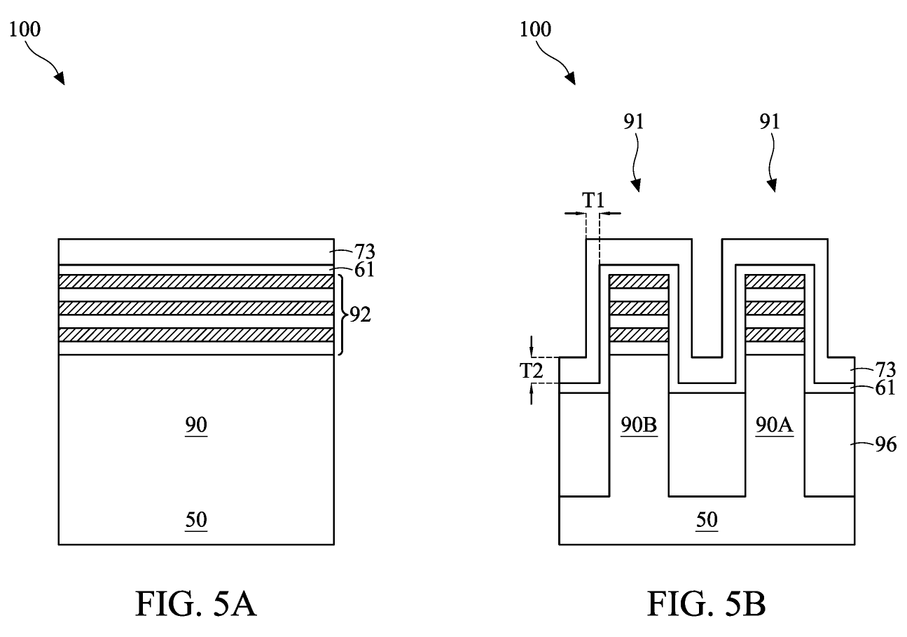

Next, in FIGS. 5A and 5B, a hard mask layer 73 is formed over the liner layer 61. The hard mask layer 73 is formed of a material different from the liner layer 61 and the STI regions 96. In some embodiments, the material of the hard mask layer 73 is chosen to provide high etching selectivity from the material of the STI regions 96, such that in a subsequent sheet formation process (e.g., an etching process) to form nanostructures (e.g., nanosheets), the hard mask layer 73 protects the STI regions 96 to prevent loss of the STI regions 96. In an embodiment, the STI regions 96 is formed of silicon oxide, and the hard mask layer 73 is formed of silicon nitride. Besides silicon nitride, other suitable materials, such as silicon oxynitride, silicon oxycarbonitride, or the like, may also be used for the hard mask layer 73. A suitable formation method, such as CVD, plasm-enhanced CVD (PECVD), or the like, may be used to form the hard mask layer 73.

In some embodiments, the hard mask layer 73 is formed to have a non-uniform thickness. For example, the horizontal portions of the hard mask layer 73 (e.g., portions along the top surfaces of the fin structures 91 or along the upper surfaces of the STI regions 96) has a thickness T2, the vertical portions of the hard mask layer 73 (e.g., portions along the sidewalls of the fin structures 91) has a thickness T1, and the thickness T2 is larger than the thickness T1. In some embodiments, the thickness T2 is between about 1.5 times and about 3 times, such as between about twice and about three times, of the thickness T1.

The non-uniform thickness of the hard mask layer 73 provides advantages for the manufacturing of the NSFET device 100. As will be discussed in more detail hereinafter, in subsequent processing, sidewalls portions (e.g., the vertical portions) of the hard mask layer 73 and top portions (e.g., portions along the top surfaces of the fin structures 91) of the hard mask layer 73 are removed, and the bottom portions (e.g., portions along the upper surfaces of the STI regions 96) of the hard mask layer 73 remain to form the STI protection structure 68. Thicker bottom portions of the hard mask layer 73 in the STI protection structure 68 provide enhanced protection for the STI regions 96 during the subsequent sheet formation process. In addition, thinner sidewall portions of the hard mask layer 73 in the STI protection structure 68 allows easier removal of the sidewall portions, thus shorting the process time and increasing throughput of the production. Furthermore, as feature sizes continue to shrink in advanced semiconductor manufacturing, the distance between adjacent fin structures 91 may pose a challenge for depositing materials (e.g., the hard mask layer 73) in the trenches between adjacent fin structure 91, due to the high aspect ratio of the trenches. By forming the sidewall portions of the hard mask layer 73 to be thinner, the disclosed method herein allows the hard mask layer 73 with a sufficient thickness to be formed at the bottoms of the trenches (e.g., on the upper surfaces of the STI regions 96). The thinner sidewall portions of the hard mask layer 73 may also prevent top portions (which are disposed over the top surfaces of fin structures 91) of the hard mask layer 73 on adjacent fin structures 91 from merging together. Merging of the top portions of the hard mask layer 73 prevents further deposition of the hard mask layer 73 on the upper surfaces of the STI regions 96, which may cause failure in the formation of the STI protection structure 68. Therefore, the thinner sidewall portions of the hard mask layer 73 may prevent device failure and loss in production yield caused by the failure in the formation of the STI protection structure.

In some embodiments, the hard mask layer 73 with non-uniform thickness is formed by a PECVD process disclosed herein. Note that in contrast to a conventional PECVD process which generally strives to form a layer of material with uniform thickness, the disclosed PECVD process is tuned to form the hard mask layer 73 with non-uniform thickness. The disclosed PECVD process includes multiple deposition cycles, where each deposition cycle includes a plurality of processing steps performed in a process chamber. In some embodiments, the plurality of processing steps in a deposition cycle includes a first processing step, a second processing step, and a third processing steps performed sequentially. After each of the first, the second, and the third processing steps, the un-used precursors, the plasma generated during the processing step, and/or the byproduct(s) of the processing step (if any), are evacuated (e.g., purged) from the process chamber by, e.g., a vacuuming mechanism. For ease of discussion, the layer of material formed after completion of each deposition cycle of the PECVD process is referred to as a sublayer of the hard mask layer 73.

In some embodiments, the first processing step in a deposition cycle is a plasma process that forms a layer of silicon on the underlying layer (e.g., the liner layer 61, or a previously formed sublayer of the hard mask layer 73). In an example embodiment, a gas source comprising a silicon-containing precursor (e.g., silane (SiH4)) is supplied to the process chamber. A radio-frequency (RF) power source is turned on to ignite the gas source into a plasma. The plasma energy breaks down the precursor molecules into reactive species, and the reactive species diffuse to the underlying layer and react to form the layer of silicon. In some embodiments, an etching gas (e.g., H₂) is included in the gas source with the silicon-containing precursor. During the first processing step, the plasma of the etching gas (e.g., plasma of H₂) etches the silicon layer, and may help to control (e.g., slow down) the growth rate of the silicon layer and to achieve better control of the profile of the silicon layer. After the first processing step, un-used precursor, etching gas, plasma, and/or byproduct(s) (if any) are evacuated from the process chamber.

In some embodiments, the second processing step in a deposition cycle is a plasma process (e.g., a plasma etching process) that adjusts (e.g., modifies, changes) the thicknesses of the horizontal portions (e.g., portions along the top surfaces of the fin structures 91) of the silicon layer and the vertical portions (e.g., portions along the sidewalls of the fin structures 91) of the silicon layer formed in the first processing step. In an example embodiment, the plasma processing increases a ratio between the thickness of the horizontal portions of the silicon layer and the thickness of the vertical portions of the silicon layer. The plasma process (e.g., a plasma etching process) achieves the adjustment by adjusting the ratio between the vertical etching rate and the horizontal etching rate of the plasma process, as an example. By adjusting the process conditions of the plasma process, such as the pressure, the temperature, the power of the RF power source, the incident angle of the ions, and/or the duration of the plasma process, the ratio between the vertical etching rate and the horizontal etching rate are adjusted. For example, the horizontal etching rate may be adjusted to be higher than the vertical etching rate, such that the ratio between the thickness of the horizontal portions of the silicon layer and the thickness of the vertical portions of the silicon layer is increased after the plasma process of the second processing step.

In some embodiments, the plasma process of the second processing step is performed using a gas source comprising hydrogen gas (H₂). The gas source is ignited into a plasma by the RF power source, and the H₂ plasma etches the silicon layer formed in the first processing step. Therefore, the second processing step may also be referred to as a hydrogen plasma etching process or hydrogen plasma treatment of the silicon layer. Compared with other more aggressive plasma etching chemicals (e.g., a fluorine-based chemical), hydrogen plasma etches the silicon layer slower and less aggressively, thus allowing for better control of the thicknesses of the horizontal/vertical portions of the silicon layer. After the second processing step, un-used etching gas, plasma, and/or byproduct(s) (if any) are evacuated from the process chamber.

In some embodiments, the third processing step in a deposition cycle is a plasma process performed to nitridize the silicon layer into a silicon nitride layer, and therefore, may also be referred to as a nitridation process. In some embodiments, the plasma process of the third processing step is performed using a gas source comprising nitrogen gas (N₂). The gas source is ignited into a plasma by the RF power source, and the N₂ plasma reacts with the silicon layer and turns the silicon layer into a silicon nitride layer. Therefore, after the third processing step, a sublayer of the hard mask layer 73 (e.g., a sublayer of silicon nitride) is formed. After the third processing step, un-used gas source, plasma, and/or byproduct(s) (if any) are evacuated from the process chamber. The above described deposition cycle is repeated, until the thickness of the hard mask layer 73 reaches a target value. A thickness (e.g., average thickness) of the hard mask layer 73 may be between about 5 nm and about 12 nm, such as 6 nm, 10 nm, as examples.

Note that in the above example, silicon nitride is used as a non-limiting example of the material of the hard mask layer 73. Other suitable material, such as silicon oxynitride, silicon oxycarbonitride, or the like, may also be used for the hard mask layer 73, and the deposition method disclosed above (e.g., the PECVD process) may be adapted to form the different materials for the hard mask layer 73, as skilled artisans readily appreciate.

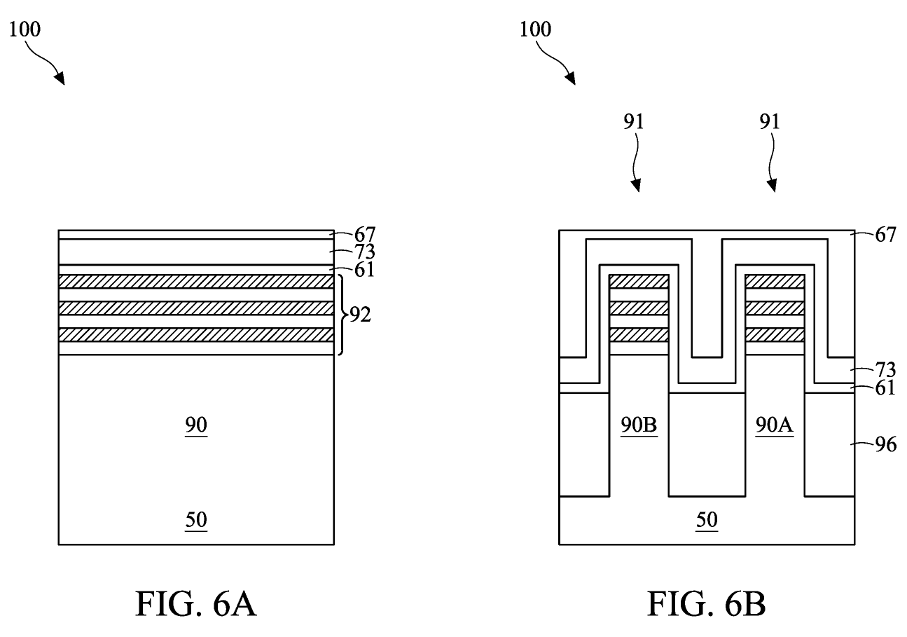

Next, in FIGS. 6A and 6B, a mask layer 67 is formed over the hard mask layer 73. In some embodiments, the mask layer 67 is a Bottom Anti-Reflective Coating (BARC) layer typically used in a tri-layered photoresist. The BARC layer may be a carbon-containing material, such as spin-on glass (SOG) carbon, as an example. Therefore, the mask layer 67 may also be referred to as a BARC layer 67 in the discussion herein, with the understanding that other suitable materials may also be used. As illustrated in FIGS. 6A and 6B, the BARC layer 67 fills the trenches between adjacent fin structures 91, and covers the top surfaces of the fin structures 91.

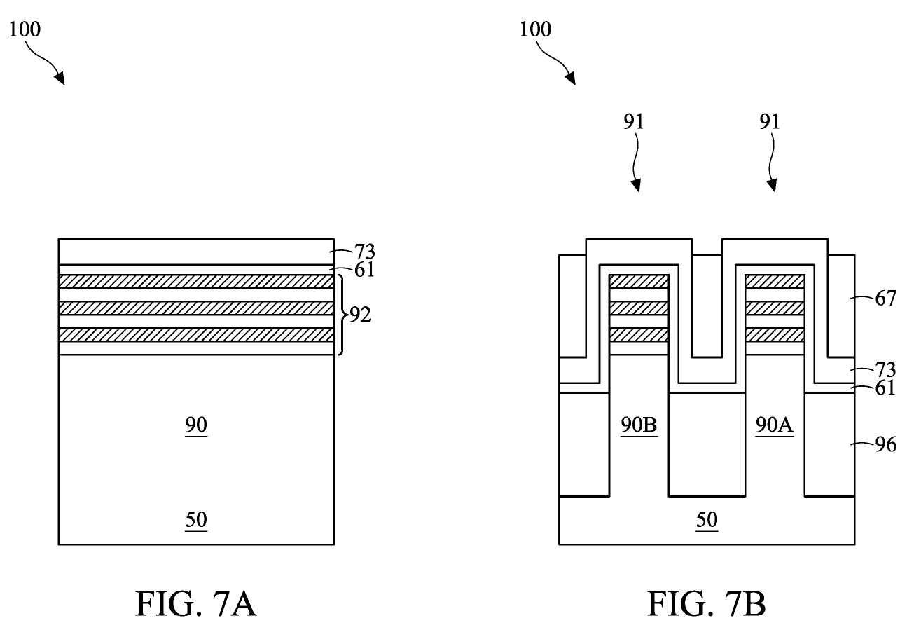

Next, in FIGS. 7A and 7B, the BARC layer 67 is etched back to expose the top portions of the hard mask layer 73 disposed on the top surfaces of the fin structures 91. A suitable etching process, such as a dry etching process, a wet etching process, combinations thereof, or the like, may be performed to etch back the BARC layer 67. The etching process may be a timed process to etch back the BARC layer 67 by a pre-determined amount. In some embodiments, the etching process is performed using an etchant selective to (e.g., having a higher etching rate for) the material of the BARC layer 67, such that the BARC layer 67 is removed without substantially attacking the hard mask layer 73.

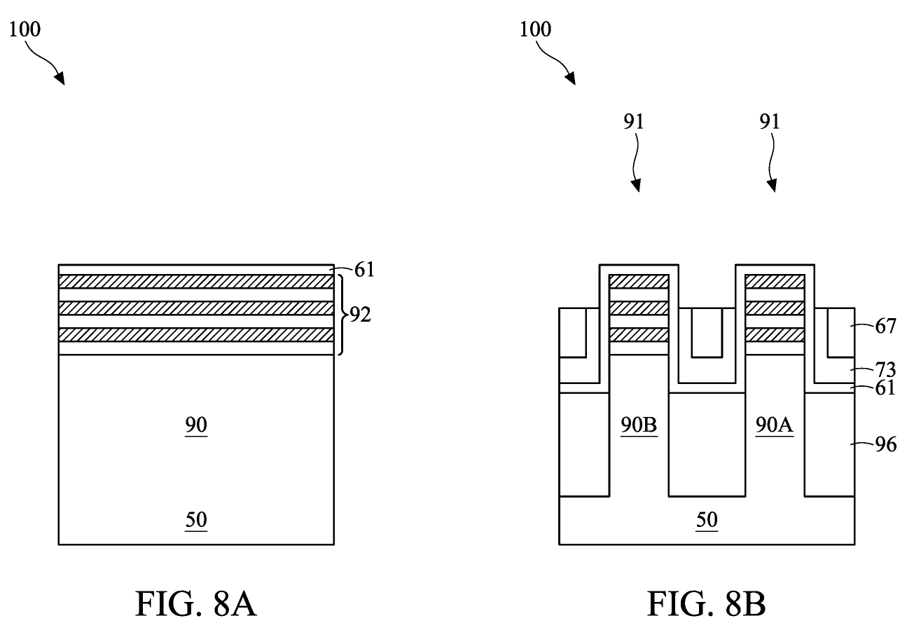

Next, in FIGS. 8A and 8B, the exposed top portions of the hard mask layer 73 are removed by an etching process. For example, a dry etching process using, e.g., a gas source comprising a fluorine-based etching gas, may be performed to remove the exposed top portions of the hard mask layer 73. The gas source may include NF₃ and H₂, as an example. As another example, a wet etching process using, e.g., phosphoric acid (H₃PO₄), may be performed to remove the exposed top portions of the hard mask layer 73. In the illustrated example of FIGS. 8A and 8B, the etching process also recesses the BARC layer 67 and removes upper sidewall portions of the hard mask layer 73. Due to the etching selectivity between the liner layer 61 and the BARC layer 67/the hard mask layer 73, the liner layer 61 remains substantially un-etched, and covers the sidewalls of the fin structures 91 and the top surfaces of the fin structures 91. Therefore, the liner layer 61 protects the layer stacks 92 (and subsequently formed nanostructures 54) from damage caused by the etching processes used in forming the STI protection structure 68.

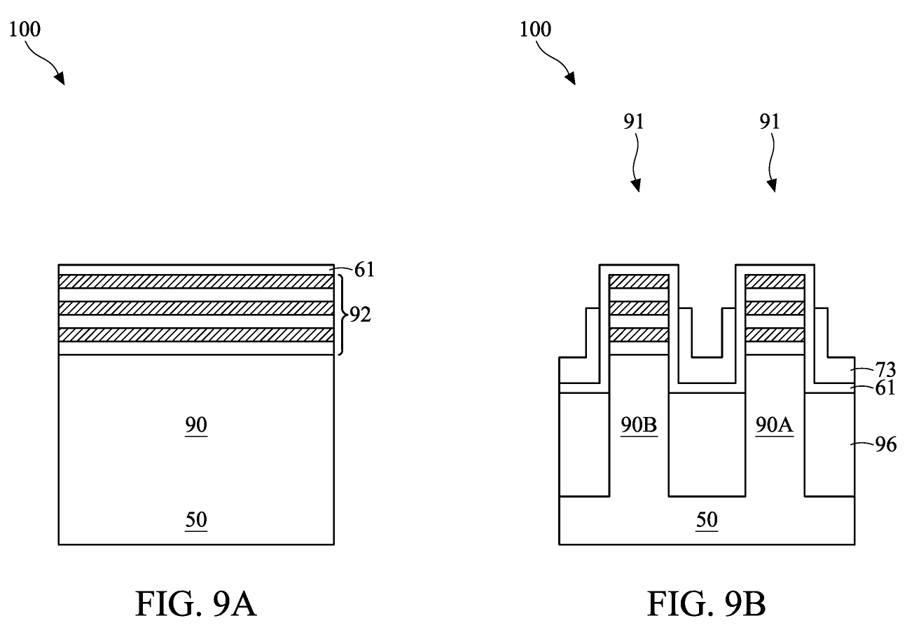

Next, in FIGS. 9A and 9B, the remaining portions of the BARC layer 67 are removed by an etching process. The etching process may be dry etching, wet etching, combinations thereof, or the like. In some embodiments, the etching process is a plasma etching process performed using a gas source comprising H₂ and N₂ gases. After the removal of the remaining portions of the BARC layer 67, remaining portions of the hard mask layer 73 are exposed. The remaining portions of the hard mask layer 73 include sidewall portions along the sidewalls of the fin structures 91, and include bottom portions along the upper surfaces of the STI region 96.

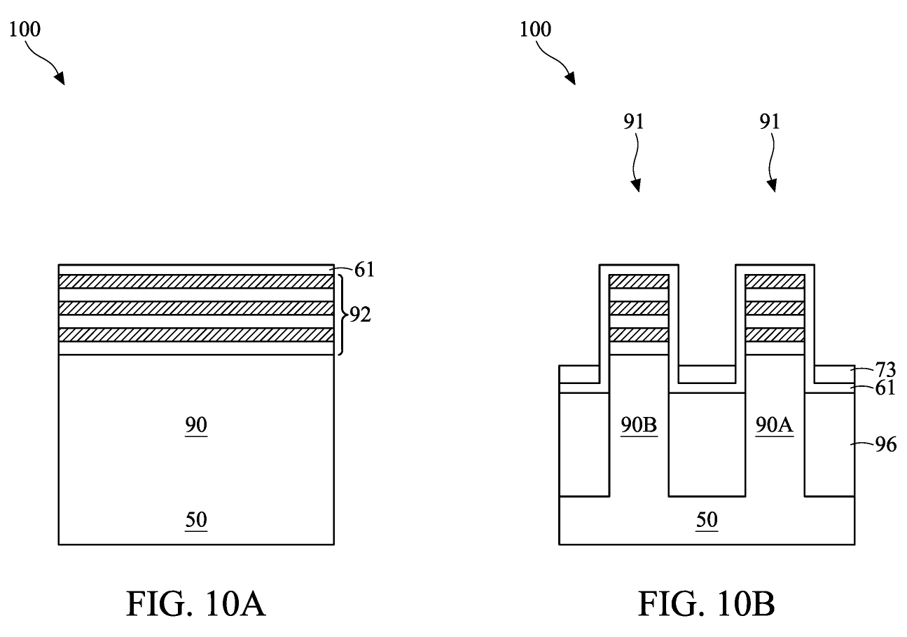

Next, in FIGS. 10A and 10B, the sidewall portions of the hard mask layer 73 are removed by an etching process. The etching process may be a dry etching process, a wet etching process, combinations thereof, or the like. In some embodiments, a dry etching process is performed to remove the sidewall portions of the hard mask layer 73 using a fluorine-based etching gas, such as HF, NF₃, or combinations thereof. In some embodiments, a wet etching process is performed to remove the sidewall portions of the hard mask layer 73. In an embodiment, the wet etching process is performed by etching using a first etchant (e.g., H₃PO₄) for a first duration of time, then etching using a second etchant (e.g., SC1, which is a mixture of deionized water, ammonia water, and hydrogen peroxide) for a second duration of time.

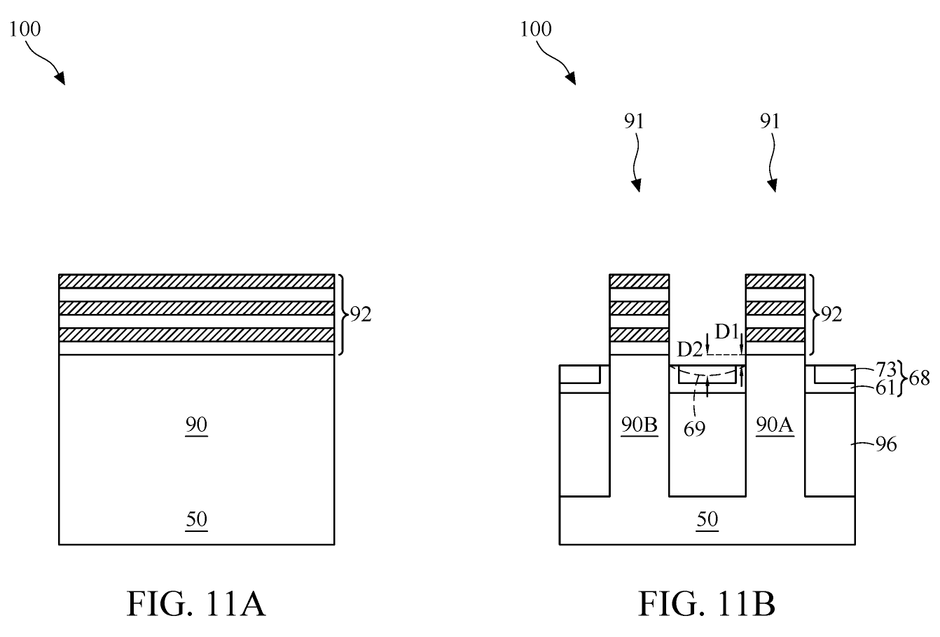

Note that in FIGS. 10A and 10B, the etching process may be isotropic, and therefore, not only removes (e.g., completely removes) the sidewall portions of the hard mask layer 73, but also removes some portions (e.g., portions distal from the substrate 50) of the bottom portions of the hard mask layer 73. In other words, the thickness of the bottom portions of the hard mask layer 73 is reduced by the etching process used to remove the sidewall portions of the hard mask layer 73. Recall that the PECVD process used to form the hard mask layer 73 is tuned to form thicker bottom portions for the hard mask layer 73. The thicker bottom portions ensure that after the etching process to remove the sidewall portions of the hard mask layer 73, the remaining bottom portions of the hard mask layer 73 have enough thickness to properly form the STI protection structure 68 (see, e.g., FIGS. 11A and 11B).

Next, in FIGS. 11A and 11B, portions of the liner layer 61 disposed above the remaining bottom portions of the hard mask layer 73 are removed by an etching process. A suitable etching process, such as dry etching process, wet etching process, combinations thereof, or the like, may be used to remove the portions of the liner layer 61. In an embodiment, the portions of the liner layer 61 is removed by a wet etching process performed using a mixture of HF and SC1. After the etching process, the remaining portions of the liner layer 61 and the remaining portions of the hard mask layer 73 form the STI protection structure 68. As illustrated in FIGS. 11A and 11B, the STI protection structure 68 covers (e.g., contacts and extends along) the upper surfaces of the STI regions 96. The STI protection structure 68 protects (e.g., shields) the STI regions 96 in the subsequent sheet formation process to prevent or reduce loss of the STI regions 96.

As illustrated in FIGS. 11A and 11B, the liner layer 61 of the STI protection structure 68 extends along the sidewalls and the bottom surface of the hard mask layer 73 of the STI protection structure 68. In some embodiments, the upper surface of the STI protection structure 68 is a flat surface, as illustrated in FIG. 11B. In some embodiments, the upper surface of the STI protection structure 68 is a concave surface, as illustrated by the dashed line 69 in FIG. 11B. For example, a vertical distance D1 between the upper surface of the STI protection structure 68 and the upper surface of the fin 90, measured at a first location where the STI region 96 contacts the fin 90, is smaller than a vertical distance D2 between the upper surface of the STI protection structure 68 and the upper surface of the fin 90, measured at a second location midway between two adjacent fins 90. The vertical distance D1 may be, e.g., 8 nm, and the vertical distance D2 may be, e.g., 10 nm, as an example. Subsequent drawings use the example where the STI protections structure 68 has a flat surface, with the understanding that the upper surface of the STI protection structure 68 may have other shapes, such as a concave surface, or a convex surface. These and other variations are fully intended to be included within the scope of the present disclosure.

Next, in FIGS. 12A-12C, a dummy dielectric layer 97 is formed over the STI protection structure 68 and over the sidewalls and the top surfaces of the fin structure 91. The dummy dielectric layer 97 may be, for example, silicon oxide, silicon nitride, a combination thereof, or the like, and may be deposited or thermally grown according to acceptable techniques. In an embodiment, a layer of silicon is conformally formed over the layer stack 92 and over the upper surface of the STI protection structure 68, and a thermal oxidization process is performed to convert the deposited silicon layer into an oxide layer as the dummy dielectric layer 97.

Next, dummy gates 102 are formed over the fin structures 91. To form the dummy gates 102, a dummy gate layer may be formed over the dummy dielectric layer 97. The dummy gate layer may be deposited over the dummy dielectric layer 97 and then planarized, such as by a CMP. The dummy gate layer may be a conductive material and may be selected from a group including amorphous silicon, polycrystalline-silicon (polysilicon), poly-crystalline silicon-germanium (poly-SiGe), or the like. The dummy gate layer may be deposited by physical vapor deposition (PVD), CVD, sputter deposition, or other techniques known and used in the art.

Masks 104 are then formed over the dummy gate layer. The masks 104 may be formed from silicon nitride, silicon oxynitride, combinations thereof, or the like, and may be patterned using acceptable photolithography and etching techniques. In the illustrated embodiment, the mask 104 includes a first mask layer 104A (e.g., a silicon oxide layer) and a second mask layer 104B (e.g., a silicon nitride layer). The pattern of the masks 104 is then transferred to the dummy gate layer by an acceptable etching technique to form the dummy gates 102, and then transferred to the dummy dielectric layer by acceptable etching technique to form dummy gate dielectric 97. The dummy gates 102 cover respective channel regions of the layer stacks 92. The pattern of the masks 104 may be used to physically separate each of the dummy gates 102 from adjacent dummy gates. The dummy gates 102 may also have a lengthwise direction substantially perpendicular to the lengthwise direction of the fin structures 91. The dummy gate 102 and the dummy gate dielectric 97 are collectively referred to as dummy gate structure.

Next, a gate spacer layer 108 is formed by conformally depositing an insulating material over the layer stacks 92, the STI protection structure 68, and the dummy gates 102. The insulating material may be silicon nitride, silicon carbonitride, a combination thereof, or the like. In some embodiments, the gate spacer layer 108 includes multiple sublayers. For example, a first sublayer (sometimes referred to as a gate seal spacer layer) may be formed by thermal oxidation or a deposition, and a second sublayer (sometimes referred to as a main gate spacer layer) may be conformally deposited on the first sublayer.

FIGS. 12B and 12C illustrate cross-sectional views of the NSFET device 100 in FIG. 12A along cross-sections E-E and F-F in FIG. 12A, respectively. The cross-sections E-E and F-F correspond to cross-sections D-D and A-A in FIG. 1, respectively. Note that FIGS. 12A illustrates the cross-sectional view along the longitudinal direction (e.g., a current flow direction) of one of the fins 90, the cross-sectional views along the longitudinal directions (e.g., current flow directions) of other fins 90 are the same or similar unless otherwise specified. In addition, FIG. 12A illustrates two dummy gates 102 as a non-limiting example, the number of dummy gates 102 over the fins 90 may be any suitable number.

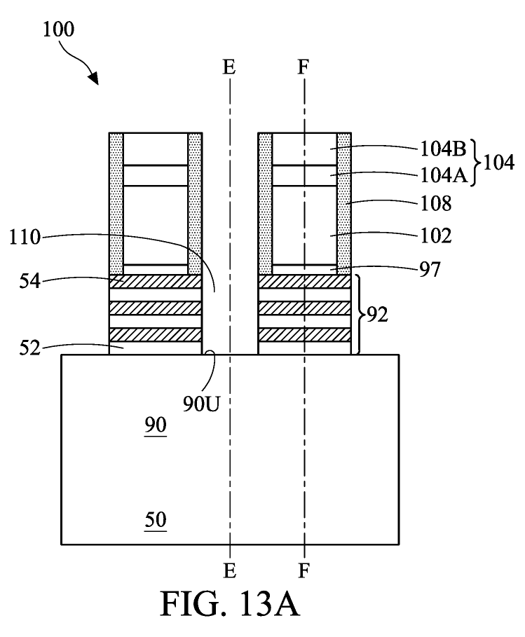

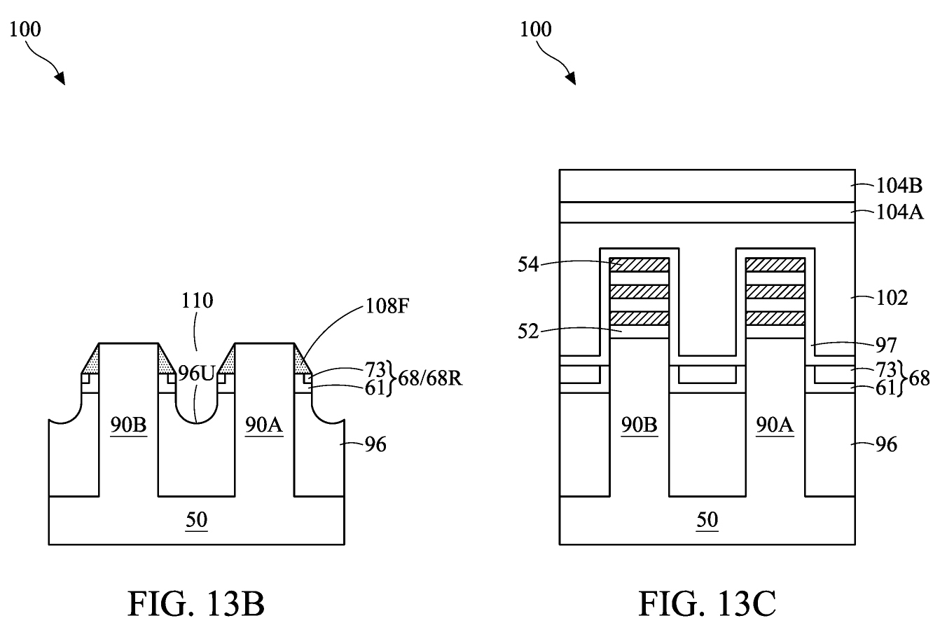

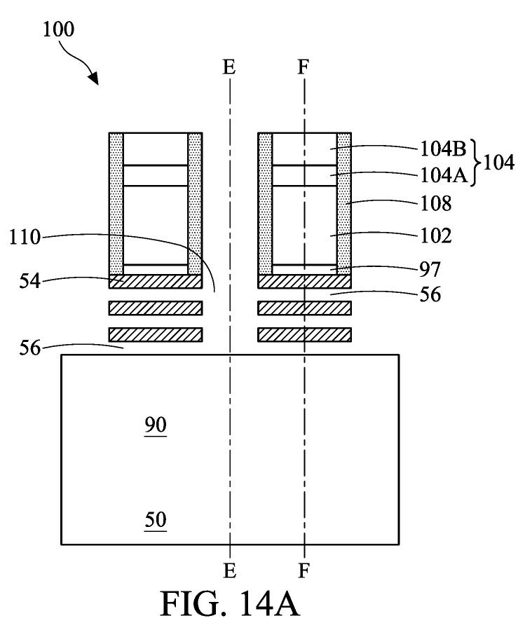

Next, in FIGS. 13A-13C, the gate spacer layers 108 are etched by an anisotropic etching process to form gate spacers 108. The anisotropic etching process may remove horizontal portions of the gate spacer layer 108 (e.g., portions over the STI regions 96 and the dummy gates 102), with remaining vertical portions of the gate spacer layer 108 along sidewalls of the dummy gates 102 and the dummy gate dielectric 97 forming the gate spacers 108. In addition, the remaining vertical portions of the gate spacer layer 108 along sidewalls of the fins 90 form fin spacers 108F (see, e.g., FIG. 13B).

After the formation of the gate spacers 108, implantation for lightly doped source/drain (LDD) regions (not shown) may be performed. Appropriate type (e.g., p-type or n-type) impurities may be implanted into the exposed layer stacks 92 and/or semiconductor fins 90. The n-type impurities may be any suitable n-type impurities, such as phosphorus, arsenic, antimony, or the like, and the p-type impurities may be any suitable p-type impurities, such as boron, BF₂, indium, or the like. The lightly doped source/drain regions may have a concentration of impurities of from about 10¹⁵ cm⁻³ to about 10¹⁶ cm⁻³. An anneal process may be used to activate the implanted impurities.

Next, openings 110 (which may also be referred to as recesses or source/drain openings) are formed in the layer stacks 92. The openings 110 may extend through the layer stacks 92 and into the fins 90. The openings 110 may be formed by an anisotropic etching process using, e.g., the dummy gates 102 and the gate spacers 108 as an etching mask. Upper surfaces 90U of the fins 90 are exposed at the bottoms of the openings 110. Sidewalls of the openings 110 expose the first semiconductor material 52 and the second semiconductor material 54.

In the example of FIG. 13B, the anisotropic etching process for forming the source/drain openings 110 removes portions of the STI protection structure 68 that are disposed beyond sidewalls of the fin spacers 108F, and also removes portions of the underlying STI regions 96, thereby resulting in recesses in the STI regions 96. FIG. 13B shows curved (e.g., concave) upper surfaces 96U of the STI regions 96 due to the etching of the STI regions 96. Note that portions of the STI protection structure 68 under (e.g., directly under) the dummy gates 102 are shielded from the anisotropic etching process, thus remain intact.

As illustrated in FIG. 13B, portions of the STI protection structure 68 remain under the fin spacers 108F, and are referred to as remaining portions 68R of the STI protection structure 68. The remaining portions 68R of the STI protection structure 68 protect the fins 90 from over-etching by the anisotropic etching process for forming the source/drain openings 110. Without the remaining portions 68R of the STI protection structure 68, over-etching by the anisotropic etching process may expose and/or remove portions of the fins 90 disposed below the fin spacers 108F. The un-intended removal of the portions of the fins 90 by the over-etching may cause the fins 90 to collapse, and/or may cause un-intended growth of epitaxial source/drain material from the un-intendedly exposed portions of the fins 90 during the subsequent source/drain regions formation process. The un-intended growth of epitaxial source/drain material between adjacent fins 90 may cause electrical short between the adjacent source/drain regions, thus causing device failure. The disclosed method herein, by having the remaining portions 68R of the STI protection structure 68, avoids the above over-etching related issues, thereby preventing or reducing the likelyhood of device failure and improving production yield. This illustrate another advantage of the presently disclosure.

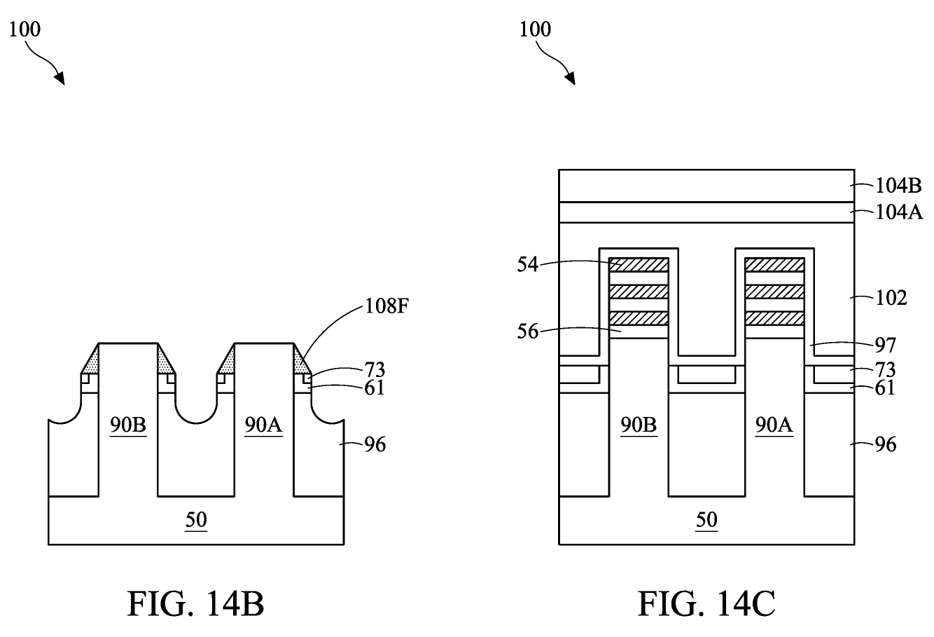

Next, in FIGS. 14A-14C, the first semiconductor material 52 under the dummy gates 102 and exposed by the openings 110 are removed. The first semiconductor material 52 may be removed by performing an isotropic etching process such as wet etching or the like using etchant(s) which is selective to the materials of the first semiconductor material 52, while the second semiconductor material 54, the fins 90, the STI regions 96 remain relatively unetched as compared to the first semiconductor material 52. In embodiments in which the first semiconductor material 52 include, e.g., SiGe, and the second semiconductor material 54 include, e.g., Si or SiC, tetramethylammonium hydroxide (TMAH), ammonium hydroxide (NH₄OH), or the like may be used to selectively remove the first semiconductor material 52. After the first semiconductor material 52 is removed, gaps 56 (e.g., empty spaces) are formed between adjacent layers of the second semiconductor material 54, and between the fin 90 and a lowermost layer of the second semiconductor material 54.

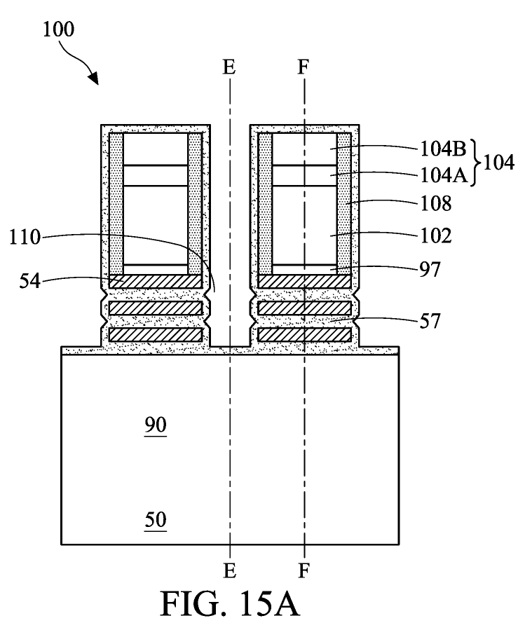

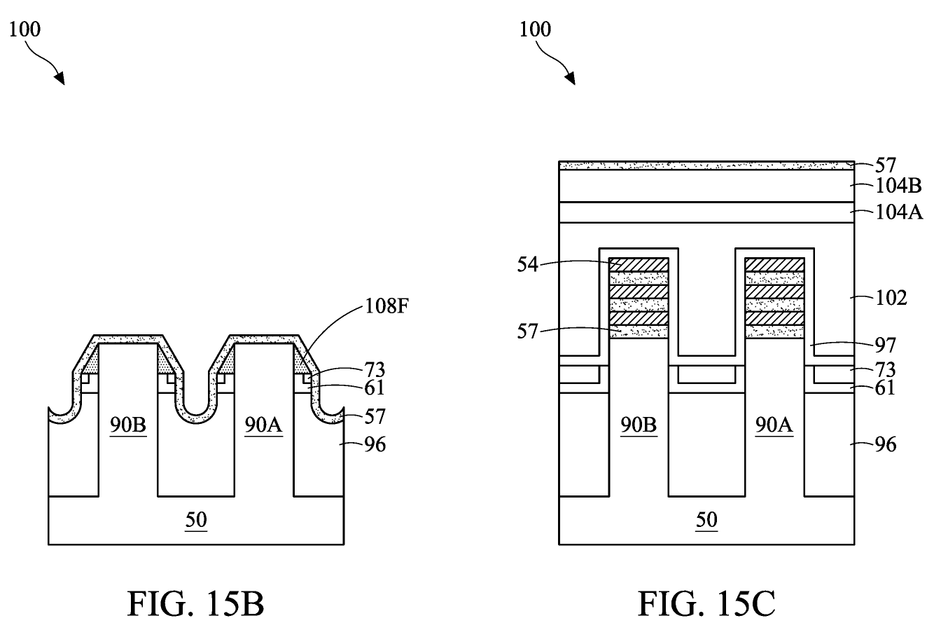

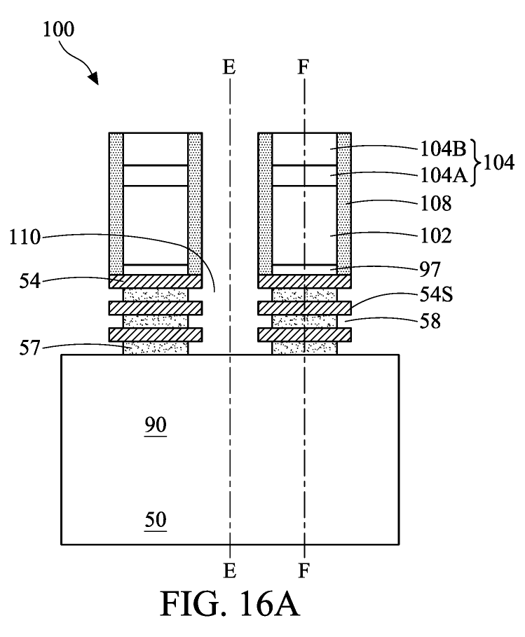

Next, in FIGS. 15A-15C, a disposable material 57 (may also be referred to as a sacrificial material) is deposited in the openings 110 to line the sidewalls and bottoms of the openings 110. The disposable material 57 also fills the gaps 56. The disposable material 57 may be deposited by a conformal deposition process, such as CVD, ALD, or the like. The disposable material 57 may be a dielectric material. In some embodiments, the disposable material 57 includes one or more layers of silicon oxide (SiO), silicon oxynitride (SiON), aluminum oxide (Al₂O₃), or the like. These materials are selected for their properties, such as etching selectivity, which allows for precise removal during the manufacturing process without adversely affecting the adjacent and underlying structures. The choice of the disposable material 57 may depend on the specific requirements of the semiconductor device being fabricated and the desired electrical and physical properties of the final product.

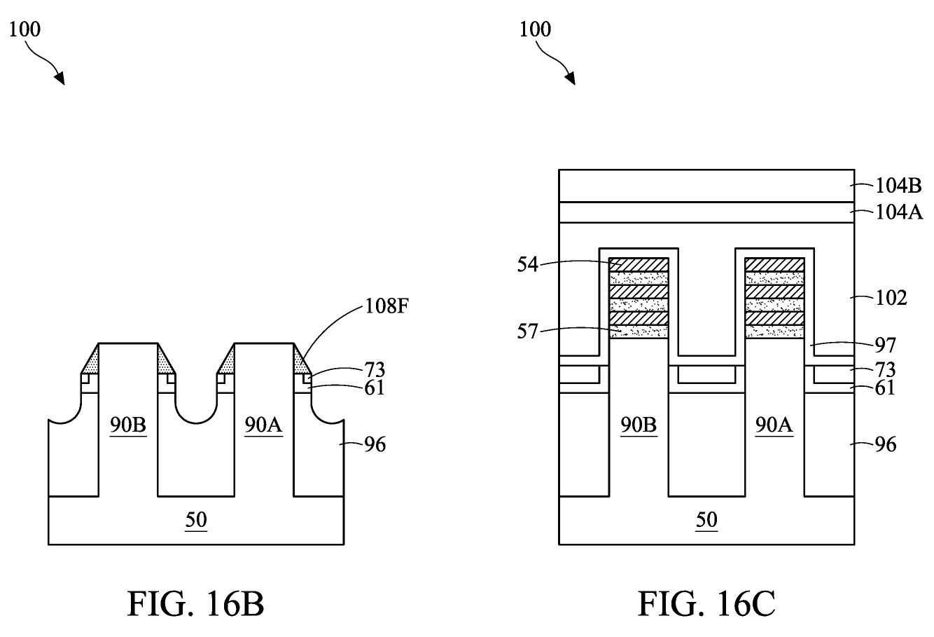

Next, in FIGS. 16A-16C, the disposable material 57 disposed outside the gaps 56 are removed, and sidewalls of the remaining portions of the disposable material 57 are recessed from respective sidewalls 54S of the second semiconductor material 54 to form sidewall recesses 58.

In some embodiments, an anisotropic etching process, e.g. a dry etching process such as a plasma etching process, is performed to remove the disposable material 57 disposed outside the gaps 56. Next, an isotropic etching process, such as a wet etching process, is performed to recess the remaining portions of the disposable material 57 to form the sidewall recesses 58. The dry etching process and the wet etching process may use etchants selective to the disposable material 57, such that the disposable material 57 is etched without substantially attacking other material(s) and/or structures. In some embodiments, multiple etching cycles, where each etching cycle includes the dry etching process followed by the wet etching process, are performed to remove the disposable material 57 and to form the sidewall recesses 58. The etching cycles are repeated until sidewalls of the disposable material 57 are recessed past sidewalls 54S of the second semiconductor material 54. In some embodiments, the disposable material 57 is etched by a wet etching process using hydrogen fluoride, diluted hydrogen fluoride, another fluorine-based etchant, or the like as an etchant. The wet etching process is performed until sidewalls of the disposable material 57 are recessed past sidewalls 54S of the second semiconductor material 54. The remaining portions of the disposable material 57, which are interposed between layers of the second semiconductor material 54, or between the fins 90 and a lowermost layer of the second semiconductor material 54, may be referred to as disposable oxide interposers (DOIs). In the subsequent sheet formation process, the DOIs are selectively removed to release the layers of the second semiconductor material 54 to form nanostructures 54 (e.g., nanosheets, or nanowires). This process may be referred to as a DOI process.

Replacing the first semiconductor material 52 with the disposable material 57 in the DOI process may provide advantages. To appreciate the advantages, consider a reference manufacturing process where the first semiconductor material 52 is not replaced with the disposable material 57. In subsequent source/drain formation steps, one or more high temperature processes may be performed to, for example, activate the dopants in the source/drain regions. When the first semiconductor material 52 (e.g., SiGe) is exposed to high temperatures, germanium in the first semiconductor material 52 may diffuse into and mix with the second semiconductor material 54 (e.g., Si), which is referred to as intermixing between germanium and silicon. Intermixing may increase roughness at interfaces between the first semiconductor material 52 and the second semiconductor material 54, and may cause manufacturing defects that degrade the performance of the resulting devices. By replacing the first semiconductor material 52 with the disposable material 57 prior to the high temperature processes (e.g., source/drain annealing), intermixing is avoided, and manufacturing defects can be reduced and device performance can be improved. In addition, the material (e.g., SiO) of the DOIs provide excellent etching selectivity (e.g., higher than 10000) from the material (e.g. Si) of the second semiconductor material 54, thus allowing for selective removal of the DOIs in the sheet formation process with little or no damage to the nanostructures 54.

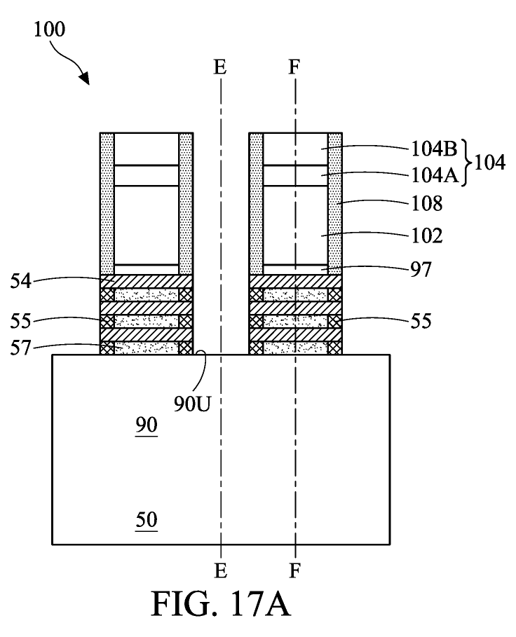

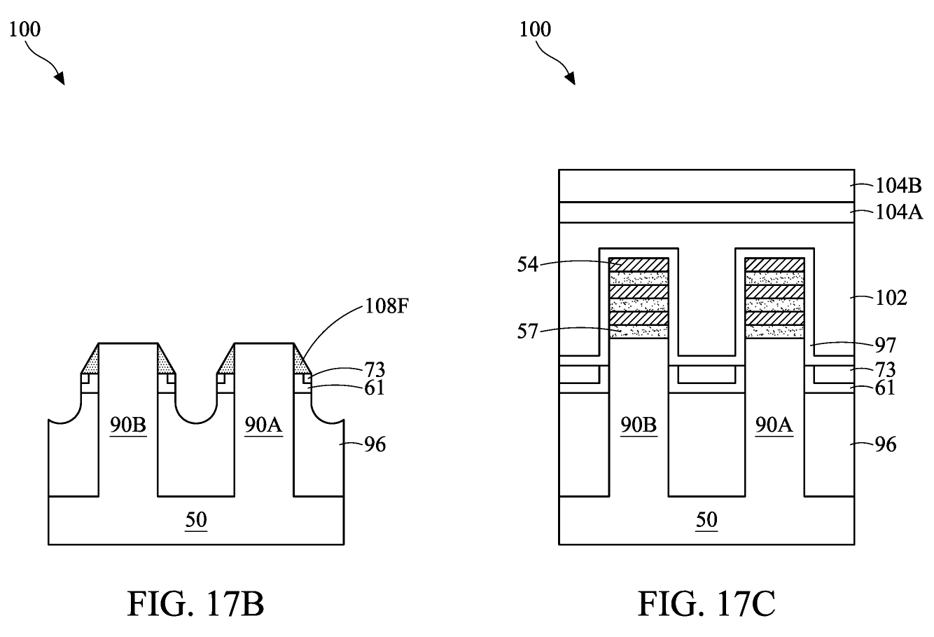

Next, in FIGS. 17A-17C, inner spacers 55 are formed in the sidewall recesses 58. FIGS. 17B and 17C illustrate cross-sectional views of the NSFET device 100 in FIG. 17A along cross-sections E-E and F-F, respectively. In some embodiments, to form the inner spacers 55, an inner spacer layer is formed (e.g., conformally) in the openings 110. The inner spacer layer also fills the sidewall recesses 58 of the sacrificial material 57. The inner spacer layer may be a suitable dielectric material, such as silicon carbonitride (SiCN), silicon oxycarbonitride (SiOCN), or the like, formed by a suitable deposition method such as PVD, CVD, ALD, or the like. Next, an etching process, such as an anisotropic etching process, is performed to remove portions of the inner spacer layers disposed outside the sidewall recesses 58 of the sacrificial material 57. The remaining portions of the inner spacer layers (e.g., portions disposed inside the sidewall recesses 58 of the sacrificial material 57) form inner spacers 55. As illustrated in FIG. 17A, the openings 110 expose sidewalls of the second semiconductor material 54 and expose upper surfaces 90U of the fins 90.

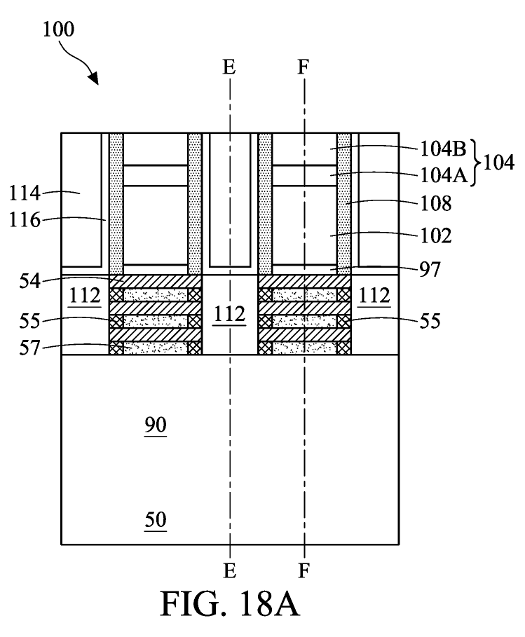

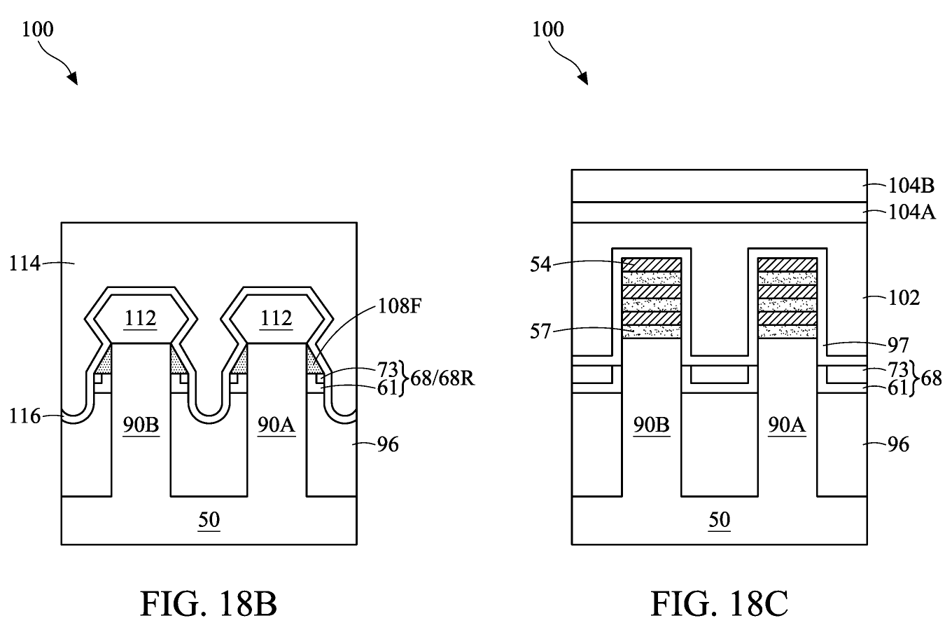

Next, in FIGS. 18A-18C, source/drain regions 112 are formed in the openings 110. In the discussion herein, source/drain region(s) may refer to a source or a drain, individually or collectively dependent upon the context. In the illustrated embodiment, the source/drain regions 112 are formed of an epitaxial material(s), and therefore, may also be referred to as epitaxial source/drain regions 112. In some embodiments, the epitaxial source/drain regions 112 are formed in the openings 110 to exert stress in the respective channel regions of the NSFET device formed, thereby improving performance. In some embodiments, the epitaxial source/drain regions 112 are formed such that the dummy gate 102 is disposed between respective neighboring pairs of the epitaxial source/drain regions 112. In some embodiments, the gate spacers 108 are used to separate the epitaxial source/drain regions 112 from the dummy gates 102 by an appropriate lateral distance so that the epitaxial source/drain regions 112 do not short out subsequently formed gates of the resulting NSFET device.

The epitaxial source/drain regions 112 are epitaxially grown in the openings 110. The epitaxial source/drain regions 112 may include any acceptable material, such as appropriate for n-type or p-type device. For example, when n-type devices are formed, the epitaxial source/drain regions 112 may include materials exerting a tensile strain in the channel regions, such as silicon, SiC, SiCP, SiP, or the like. Likewise, when p-type devices are formed, the epitaxial source/drain regions 112 may include materials exerting a compressive strain in the channel regions, such as SiGe, SiGeB, Ge, GeSn, or the like. The epitaxial source/drain regions 112 may have surfaces raised from respective surfaces of the fins 90 and may have facets.

The epitaxial source/drain regions 112 and/or the fins 90 may be implanted with dopants to form source/drain regions, similar to the process previously discussed for forming lightly-doped source/drain regions, followed by an anneal. The source/drain regions may have an impurity concentration of between about 10¹⁹ cm⁻³ and about 10²¹ cm⁻³. The n-type and/or p-type impurities for source/drain regions may be any of the impurities previously discussed. In some embodiments, the epitaxial source/drain regions 112 may be in situ doped during growth.

As a result of the epitaxy processes used to form the epitaxial source/drain regions 112, upper surfaces of the epitaxial source/drain regions 112 have facets which expand laterally outward beyond sidewalls of the fins 90. In some embodiments, adjacent epitaxial source/drain regions 112 over adjacent fins 90 remain separated after the epitaxy process is completed, as illustrated in FIG. 18B. In other embodiments, these facets cause adjacent epitaxial source/drain regions 112 to merge.

Next, a contact etch stop layer (CESL) 116 is formed (e.g., conformally) over the source/drain regions 112 and over the dummy gate 102, and a first inter-layer dielectric (ILD) 114 is then deposited over the CESL 116. The CESL 116 is formed of a material having a different etch rate than the first ILD 114, and may be formed of silicon nitride using PECVD, although other dielectric materials such as silicon oxide, silicon oxynitride, combinations thereof, or the like, and alternative techniques of forming the CESL 116, such as low-pressure CVD (LPCVD), PVD, or the like, could alternatively be used.

The first ILD 114 may be formed of a dielectric material, and may be deposited by any suitable method, such as CVD, PECVD, or FCVD. Dielectric materials for the first ILD 114 may include silicon oxide, Phospho-Silicate Glass (PSG), Boro-Silicate Glass (BSG), Boron-Doped Phospho-Silicate Glass (BPSG), undoped Silicate Glass (USG), or the like. Other insulation materials formed by any acceptable process may also be used.

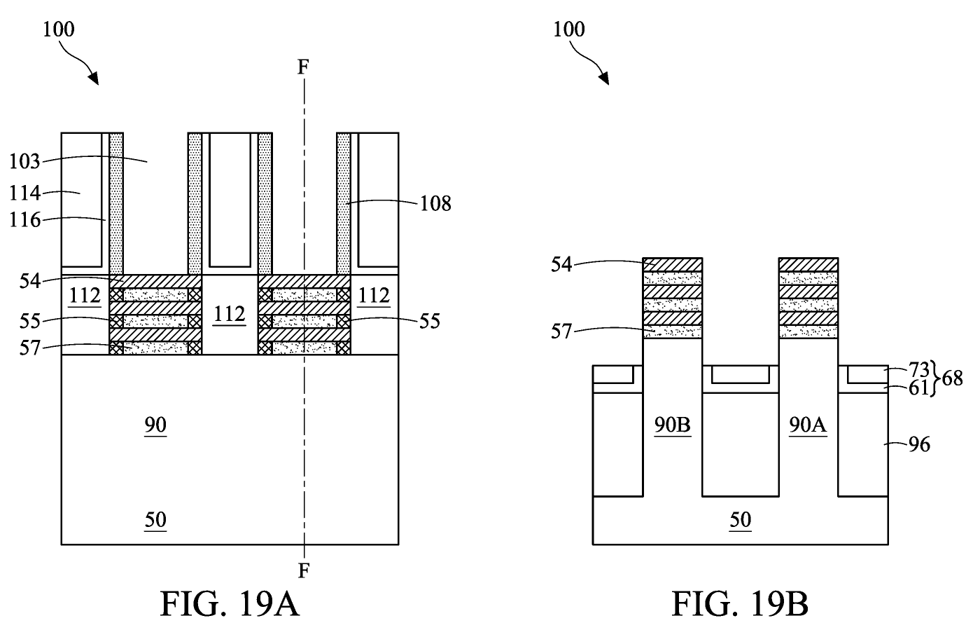

FIGS. 19A, 19B, 20A, 20B, 21A, and 21B, illustrate a replacement gate process performed subsequently, where the dummy gate structures (e.g., 102 and 97) are removed and replaced by replacement gate structures 123 (e.g., metal gate structures). The cross-sectional views corresponding to FIG. 18B are not illustrated for the replacement gate process, because such cross-sectional views are the same as FIG. 18B, in some embodiments.

Next, in FIGS. 19A and 19B, the dummy gates 102 are removed in an etching step(s), so that recesses 103 (may also be referred to as gate trenches) are formed between respective gate spacers 108. In some embodiments, the dummy gates 102 are removed by an anisotropic dry etching process. For example, the etching process may include a dry etching process using reaction gas(es) that selectively etch the dummy gates 102 without etching the first ILD 114 and the gate spacers 108. During the removal of the dummy gates 102, the dummy gate dielectric 97 may be used as an etch stop layer when the dummy gates 102 are etched. The dummy gate dielectric 97 may then be removed after the removal of the dummy gates 102.

In some embodiments, the dummy gate dielectric 97 in the recesses 103 is removed. An etching process, such as an isotropic etching process, may be performed to remove the dummy gate dielectric 97. In an embodiment, an isotropic etching process using an etching gas that comprises HF and NH₃ is performed to remove the dummy gate dielectric 97. As illustrated in FIGS. 19A and 19B, each recess 103 exposes underlying channel regions of the NSFET. Each channel region is disposed between neighboring pairs of the epitaxial source/drain regions 112.

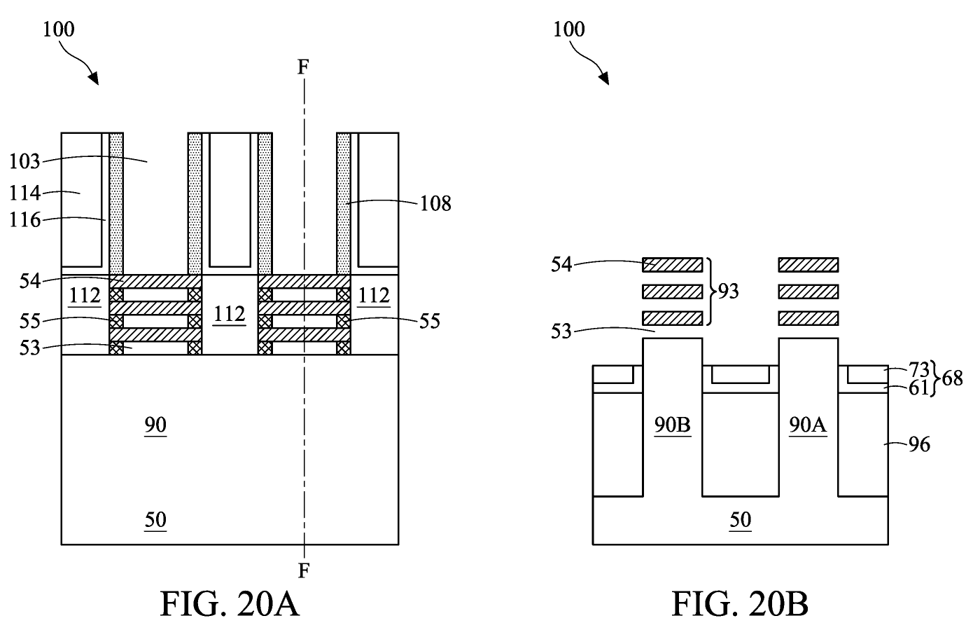

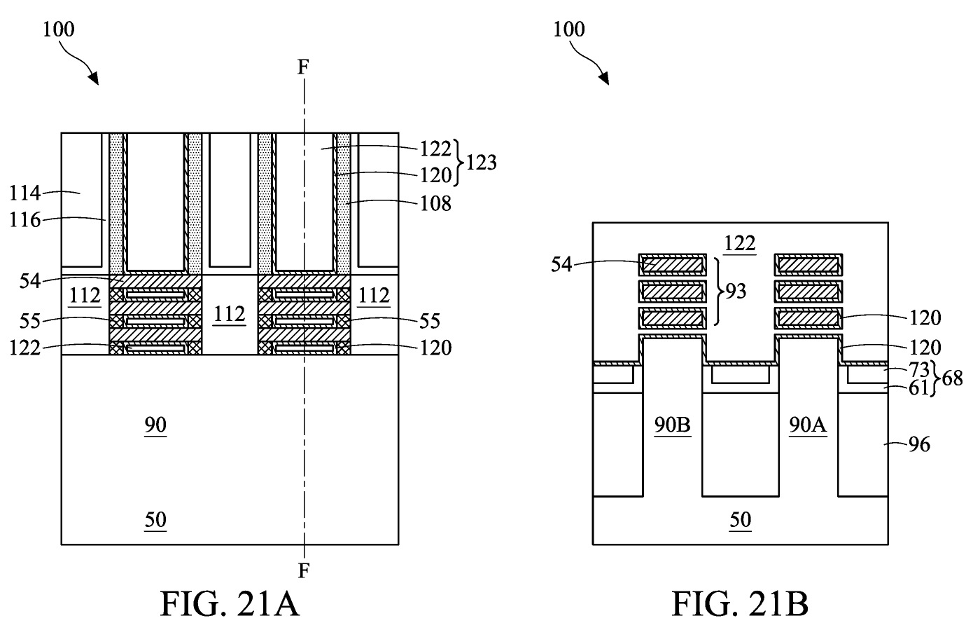

Next, in FIGS. 20A and 20B, the disposable material 57 (e.g., portions exposed by the recesses 103) is removed to release the second semiconductor material 54, which may be referred to as the sheet formation process. After the disposable material 57 is removed, the second semiconductor material 54 (e.g., portions underlying the dummy gates 102 before the dummy gates 102 are removed) forms a plurality of nanostructures 54 that extend horizontally (e.g., parallel to a major upper surface of the substrate 50). The nanostructures 54 may be collectively referred to as the channel regions 93 or the channel layers 93 of the NSFET device 100. As illustrated in FIGS. 20A and 20B, gaps 53 (e.g., empty spaces) are formed between the nanostructures 54 and between the lowermost nanostructure 54 and the fins 90 by the removal of the disposable material 57. In some embodiments, the nanostructures 54 are nanosheets or nanowires, depending on, e.g., the dimensions (e.g., size and/or aspect ratio) of the nanostructures 54.

In some embodiments, the disposable material 57 is removed by a selective etching process using an etchant that is selective to (e.g., having a higher etch rate for) the disposable material 57, such that the disposable material 57 is removed without substantially attacking the second semiconductor material 54. In some embodiments, an isotropic etching process, such as a wet etching process or the like, is performed to remove the disposable material 57. In embodiments where the disposable material 57 include, e.g., SiO₂, and the second semiconductor material 54 include, e.g., Si or SiC, hydrogen fluoride, diluted hydrogen fluoride, another fluorine-based etchant, or the like, may be used to remove the disposable material 57.

In some embodiments, a high etching selectivity of 10000 or more is achieved between the disposable material 57 and the second semiconductor material 54. In other words, the disposable material 57 is removed by the isotropic etching process at an etching rate 10000 times or more than the etching rate of the second semiconductor material 54. As a result, the etching process (e.g., the sheet formation process) used to remove the disposable material 57 cause little or no damage to the nanostructures 54.

In some embodiments, both the disposable material 57 and the STI regions 96 are formed of an oxide (e.g., silicon oxide). Without the STI protection structure 68, the sheet formation process may remove upper portions of the STI regions 96 disposed under the recesses 103, thus causing recessing of the STI regions 96. The recessing of the STI regions 96 reduces the distance between the subsequent formed replacement gate structure and the substrate. In addition, corner regions of the STI regions 96 (e.g., regions where the upper surfaces of the STI regions 96 contact the sidewalls of the fins 90) may be removed (e.g., etched away) at a faster rate than other regions of the STI regions 96 during the sheet formation process. When the subsequently formed replacement gate structure fills the removed corner regions of the STI regions 96, protrusion of the replacement gate structure occurs. The reduced distance between the replacement gate structure and the substrate, as well as the protrusion of the replacement gate structure, cause an increase in the parasitic capacitance of the replacement gate structure. The present disclosure, by forming the STI protection structure 68, prevents or reduces the likelihood of STI region loss during the sheet formation process, thus reducing the parasitic capacitance of the NSFET device formed and improving the device performance.

Next, in FIGS. 21A-21B, gate dielectric layers 120 and gate electrodes 122 are formed to form replacement gate structures 123. In some embodiments, a gate dielectric material 120 is deposited conformally in the recesses 103, such as on the top surfaces and the sidewalls of the fins 90, and on sidewalls of the gate spacers 108. The gate dielectric material 120 may also be formed on the top surface of the first ILD 114. Notably, the gate dielectric material 120 is formed to wrap around the nanostructures 54. In accordance with some embodiments, the gate dielectric material 120 comprises silicon oxide, silicon nitride, or multilayers thereof. In some embodiments, the gate dielectric material 120 comprises a high-k dielectric material, and in these embodiments, the gate dielectric material 120 may have a dielectric constant (e.g., K value) greater than about 7.0, and may include a metal oxide or a silicate of Hf, Al, Zr, La, Mg, Ba, Ti, or Pb, or combinations thereof. The formation methods of the gate dielectric material 120 may include Molecular-Beam Deposition (MBD), ALD, PECVD, and the like.

Next, a gate electrode material 122 is deposited over and around the gate dielectric material 120, and fill the remaining portions of the recesses 103. The gate electrode material may include a metal-containing material such as TiN, TiO, TaN, TaC, Co, Ru, Al, W, combinations thereof, or multi-layers thereof. For example, although a single-layer gate electrode material 122 is illustrated, the gate electrode material 122 may comprise any number of liner layers (e.g., barrier layers), any number of work function tuning layers, and a fill metal material. After the filling of the gate electrode material 122, a planarization process, such as a CMP, may be performed to remove the excess portions of the gate dielectric material 120 and the gate electrode material 122, which excess portions are over the top surface of the first ILD 114. The remaining portions of the gate electrode material 122 and the gate dielectric material 120 thus form the gate electrodes 122 and the gate dielectric layers 120, respectively, of the replacement gate structures 123 of the NSFET device 100. Each gate electrode 122 and the corresponding gate dielectric layer 120 may be collectively referred to as a gate stack 123, a replacement gate structure 123, a metal gate structure 123, or a gate structure 123. Each gate structure 123 extends around the respective nanostructures 54.

Additional processing steps may be performed to complete the fabrication of the NSFET device 100, as skilled artisans readily appreciate. For example, a second ILD may be formed over the first ILD 114. Gate contact plugs and source/drain contact plugs may be formed to extend through the second ILD and/or the first ILD 114 to be electrically coupled to the gate structures 123 and the source/drain regions 112. Next, an interconnect structure, which includes multiple dielectric layers and conductive features (e.g., vias and conductive lines) formed in the multiple dielectric layers, is formed to interconnect the underlying electrical components (e.g., NSFETs) to form functional circuits. Next, external connectors (e.g., copper pillars, conductive bumps) may be formed to be electrically coupled to the interconnect structure to provide electrical connection to external electrical devices. Dicing may be performed to separate multiple NSFET devices into separate individual devices. Details are not discussed here.

Advantages are achieved by the disclosed embodiments. For example, the use of the DOI process reduces intermixing between germanium and silicon, and provides significantly higher etching selectivity (e.g., > 10000) between the disposable material 57 and the second semiconductor material 54. As a result, when the sacrificial material 57 is removed to form the nanostructures 54, there is little or no damage to the nanostructures. As another example, the disclosed STI protection structure 68 protects the STI regions 96 (e.g., portions under the dummy gates) during the removal of the sacrificial material 57, and as a result, loss of the STI region 96 is avoided or reduced, which reduces the parasitic capacitance of the replacement gate structure 123 and improves device performance. As yet another example, the remaining portions 68R of the SIT protection structure 68 under the fin spacers 108F prevents or reduces the likelyhood of the fins 90 collapsing or un-intended growth/merging of source/drain material due to over-etching of the STI regions 96 caused by etching process used to form source/drain openings.

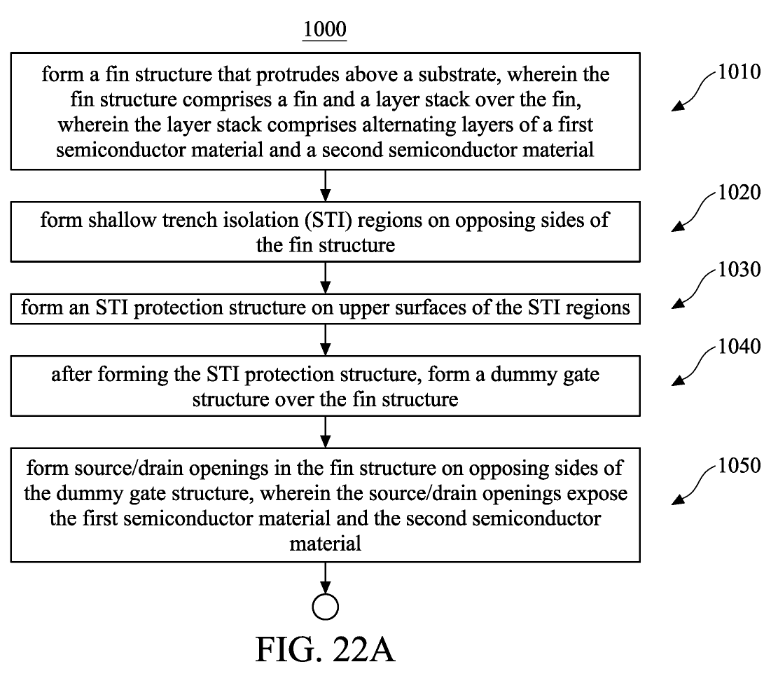

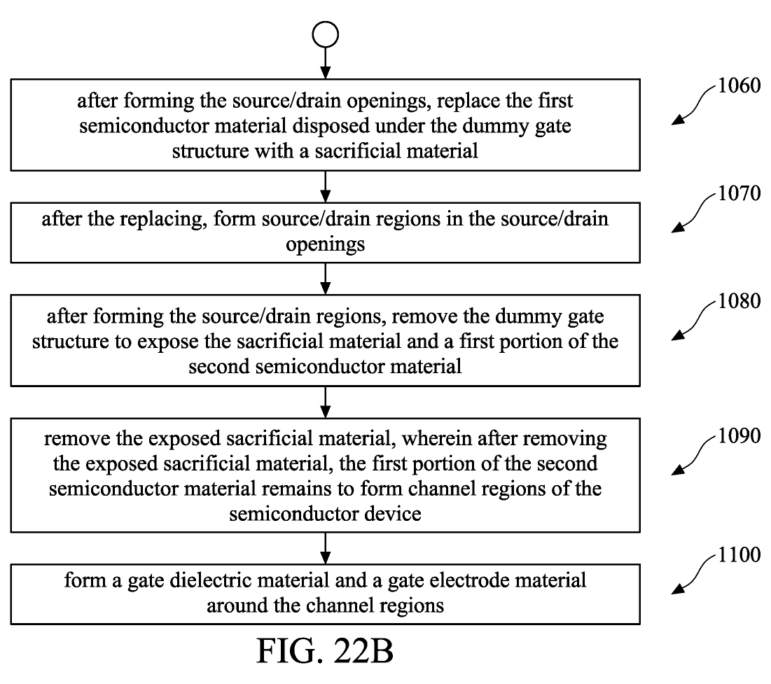

FIGS. 22A and 22B together illustrate a flow chart of a method 1000 of forming a semiconductor device, in accordance with some embodiments. It should be understood that the embodiment method shown in FIGS. 22A and 22B is merely an example of many possible embodiment methods. One of ordinary skill in the art would recognize many variations, alternatives, and modifications. For example, various steps as illustrated in FIGS. 22A and 22B may be added, removed, replaced, rearranged, or repeated.

Referring to FIGS. 22A and 22B, at block 1010, a fin structure is formed that protrudes above a substrate, wherein the fin structure comprises a fin and a layer stack over the fin, wherein the layer stack comprises alternating layers of a first semiconductor material and a second semiconductor material. At block 1020, shallow trench isolation (STI) regions are formed on opposing sides of the fin structure. At block 1030, an STI protection structure is formed on upper surfaces of the STI regions. At block 1040, after forming the STI protection structure, a dummy gate structure is formed over the fin structure. At block 1050, source/drain openings are formed in the fin structure on opposing sides of the dummy gate structure, wherein the source/drain openings expose the first semiconductor material and the second semiconductor material. At block 1060, after forming the source/drain openings, the first semiconductor material disposed under the dummy gate structure is replaced with a sacrificial material. At block 1070, after the replacing, source/drain regions are formed in the source/drain openings. At block 1080, after forming the source/drain regions, the dummy gate structure is removed to expose the sacrificial material and a first portion of the second semiconductor material. At block 1090, the exposed sacrificial material is removed, wherein after removing the exposed sacrificial material, the first portion of the second semiconductor material remains to form channel regions of the semiconductor device. At block 1100, a gate dielectric material and a gate electrode material are formed around the channel regions.

In an embodiment, a method of forming a semiconductor device includes: forming a fin structure that protrudes above a substrate, wherein the fin structure comprises a fin and a layer stack over the fin, wherein the layer stack comprises alternating layers of a first semiconductor material and a second semiconductor material; forming shallow trench isolation (STI) regions on opposing sides of the fin structure; forming an STI protection structure on upper surfaces of the STI regions; after forming the STI protection structure, forming a dummy gate structure over the fin structure; forming source/drain openings in the fin structure on opposing sides of the dummy gate structure, wherein the source/drain openings expose the first semiconductor material and the second semiconductor material; after forming the source/drain openings, replacing the first semiconductor material disposed under the dummy gate structure with a sacrificial material; after the replacing, forming source/drain regions in the source/drain openings; after forming the source/drain regions, removing the dummy gate structure to expose the sacrificial material and a first portion of the second semiconductor material; removing the exposed sacrificial material, wherein after removing the exposed sacrificial material, the first portion of the second semiconductor material remains to form channel regions of the semiconductor device; and forming a gate dielectric material and a gate electrode material around the channel regions. In an embodiment, the STI protection structure is formed to include a liner layer and a hard mask layer on the liner layer. In an embodiment, forming the STI protection structure comprises: forming a first dielectric material on the upper surfaces of the STI regions and along sidewalls and a top surface of the fin structure; forming a second dielectric material on the first dielectric material, wherein the second dielectric material is formed to have a non-uniform thickness; and recessing the first dielectric material and the second dielectric material below the layer stack, wherein after the recessing, a remaining portion of the first dielectric material and a remaining portion of the second dielectric material form the liner layer and the hard mask layer of the STI protection structure, respectively. In an embodiment, after forming the second dielectric material and before the recessing, the second dielectric material along the sidewalls of the fin structure has a first thickness, and the second dielectric material along the upper surfaces of the STI regions has a second thickness, wherein the second thickness is larger than the first thickness. In an embodiment, the first dielectric material comprises silicon oxide, and the second dielectric material comprises silicon nitride. In an embodiment, forming the second dielectric material comprises performing a plurality of deposition cycles, wherein each of the plurality of deposition cycles comprises a plurality of processing steps and is performed by: depositing a silicon layer on the first dielectric material, wherein the silicon layer along the sidewalls of the fin structure has a first thickness, and the silicon layer along the upper surfaces of the STI regions has a second thickness; increasing a ratio between the second thickness and the first thickness by performing an etching process; and after performing the etching process, treating the silicon layer with a nitridation process. In an embodiment, performing the etching process comprises performing a first plasma process using a first gas source comprising hydrogen. In an embodiment, treating the silicon layer comprises performing a second plasma process using a second gas source comprising nitrogen. In an embodiment, the method further includes, after the replacing and before forming the source/drain regions: recessing the sacrificial material from sidewalls of the second semiconductor material to form sidewall recesses in the sacrificial material; and forming inner spacers in the sidewall recesses. In an embodiment, the method further includes, after forming the source/drain regions and before removing the dummy gate structure, forming an interlayer dielectric (ILD) layer over the source/drain regions around the dummy gate structure. In an embodiment, the sacrificial material and the STI regions are formed of a first dielectric material. In an embodiment, the hard mask layer of the STI protection structure is formed of a second dielectric material, wherein the second dielectric material has a slower etch rate than the first dielectric material for an etching chemical used for the removal of the exposed sacrificial material.

In an embodiment, a method of forming a semiconductor device includes: forming a fin structure that protrudes above shallow trench isolation (STI) regions, wherein the STI regions are over a substrate and on opposing sides of the fin structure, wherein the fin structure comprises a fin and a layer stack over the fin, wherein the layer stack comprises alternating layers of a first semiconductor material and a second semiconductor material; covering upper surfaces of the STI regions with an STI protection structure, wherein the STI protection structure comprises a liner layer and a hard mask layer over the liner layer; after the covering, forming a dummy gate over the fin structure; forming source/drain openings in the fin structure on opposing sides of the dummy gate; after forming the source/drain openings, replacing the first semiconductor material disposed under the dummy gate with a sacrificial material; after the replacing, forming source/drain regions in the source/drain openings; forming an interlayer dielectric (ILD) layer over the source/drain regions and around the dummy gate; removing the dummy gate to form a gate trench in the ILD layer, wherein the gate trench exposes the sacrificial material and a first portion of the second semiconductor material; selectively removing the exposed sacrificial material, wherein after the selectively removing, the first portion of the second semiconductor material form nanostructures; and forming a replacement gate structure around the nanostructures. In an embodiment, the liner layer comprises silicon oxide, and the hard mask layer comprises silicon nitride. In an embodiment, covering the upper surfaces of the STI regions comprises: forming a first dielectric material over the upper surfaces of the STI regions, along sidewalls of the fin structure, and along a top surface of the fin structure; forming a second dielectric material over the first dielectric material, wherein the second dielectric material is formed to have a non-uniform thickness; and removing the first dielectric material and the second dielectric material from the top surface of the fin structure and from upper portions of the sidewalls of the fin structure, wherein after removing the first dielectric material and the second dielectric material, a remaining portion of the first dielectric material and a remaining portion of the second dielectric material form the liner layer and the hard mask layer of the STI protection structure, respectively. In an embodiment, the second dielectric material along the sidewalls of the fin structure is formed to be thicker than the second dielectric material along the upper surfaces of the STI regions. In an embodiment, forming the second dielectric material comprises performing a plurality of deposition cycles, wherein each of the plurality of deposition cycles comprises a plurality of processing steps and is performed by: depositing a silicon layer on the first dielectric material using a first plasma process, wherein the silicon layer along the sidewalls of the fin structure has a first thickness, and the silicon layer along the upper surfaces of the STI regions has a second thickness; increasing a ratio between the second thickness and the first thickness by performing a second plasma process; and after performing the second plasma process, nitridizing the silicon layer by performing a third plasma process.

In an embodiment, a semiconductor device includes: a substrate; a fin protruding above the substrate; shallow trench isolation (STI) regions on opposing sides of fin; an STI protection structure contacting and extending along upper surfaces of the STI regions; source/drain regions over the fin; nanostructures over the fin and between the source/drain regions; and a gate structure between the source/drain regions and around the nanostructures. In an embodiment, the STI protection structure comprises a liner layer and a hard mask layer over the liner layer, wherein the liner layer extends along sidewalls of the hard mask layer. In an embodiment, the STI regions comprises silicon oxide, and the hard mask layer comprises silicon nitride.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor device, the method comprising:
forming a fin structure that comprises a fin and a layer stack over the fin, wherein the layer stack comprises alternating layers of a first semiconductor material and a second semiconductor material, wherein the fin structure is formed to protrude above a substrate;
forming shallow trench isolation (STI) regions on opposing sides of the fin structure;
forming an STI protection structure on upper surfaces of the STI regions and along sidewalls of the fin, comprising:
forming a liner layer along the upper surfaces of the STI regions, along sidewalls of the fin structure, and along an upper surface of the fin structure;
forming a hard mask layer on the liner layer, wherein the hard mask layer is formed to have a non-uniform thickness; and
performing a plurality of etching processes to recess the liner layer and the hard mask layer below an upper surface of the fin, wherein after performing the plurality of etching processes, a remaining portion of the liner layer and a remaining portion of the hard mask layer form the STI protection structure;
forming a dummy gate structure over the fin structure and the STI protection structure;
forming source/drain openings in the fin structure on opposing sides of the dummy gate structure, wherein the source/drain openings expose sidewalls of a first portion of the first semiconductor material and sidewalls of a second portion of the second semiconductor material, wherein the first portion of the first semiconductor material and the second portion of the second semiconductor material are disposed under the dummy gate structure;
after forming the source/drain openings, replacing the first portion of the first semiconductor material with a sacrificial material;
after the replacing, forming source/drain regions in the source/drain openings;
after forming the source/drain regions, removing the dummy gate structure to expose the sacrificial material and the second portion of the second semiconductor material;
selectively removing the sacrificial material, wherein after selectively removing the sacrificial material, the second portion of the second semiconductor material forms channel regions of the semiconductor device; and
forming a gate dielectric material and a gate electrode material around the channel regions.

2. The method of claim 1, wherein the liner layer is formed of a first dielectric material, and the hard mask layer is formed of a second dielectric material different from the first dielectric material.

3. The method of claim 2, wherein selectively removing the sacrificial material comprises performing an etching process using an etchant that is selective to the sacrificial material, wherein a first etch rate of the sacrificial material for the etchant is higher than a second etch rate of the second semiconductor material for the etchant, wherein the STI regions are formed of a third dielectric material having a third etch rate for the etchant, wherein the first etch rate is substantially the same as the third etch rate.

4. The method of claim 1, wherein the hard mask layer has a horizontal portion extending along the upper surfaces of the STI regions and has a vertical portion extending along the sidewalls of the fin structure, wherein a thickness of the horizontal portion is between about 1.5 times and about 3 times a thickness of the vertical portion.

5. The method of claim 4, wherein the liner layer is formed to have a substantially uniform thickness.

6. The method of claim 1, wherein forming the hard mask layer comprises performing a plurality of deposition cycles to form a plurality of sublayers of the hard mask layer, wherein each of the plurality of deposition cycles is performed by:
forming a sublayer of silicon, wherein a horizontal portion of the sublayer of silicon extends along the upper surfaces of the STI regions, and a vertical portion of the sublayer of silicon extends along the sidewalls of the fin structure;
after forming the sublayer of silicon, increasing a ratio between a thickness of the horizontal portion of the sublayer of silicon and a thickness of the vertical portion of the sublayer of silicon by performing a plasma etching process; and
after increasing the ratio, converting the sublayer of silicon into a sublayer of nitride by performing a nitridation process.

7. The method of claim 6, wherein the plasma etching process is performed using a hydrogen plasma.

8. The method of claim 7, wherein forming the sublayer of silicon comprises performing a plasma deposition process using a gas source comprising a silicon-containing precursor and hydrogen gas, wherein the nitridation process is performed using a nitrogen plasma.

9. The method of claim 1, further comprising, after the replacing and before forming the source/drain regions, replacing end portions of the sacrificial material exposed by the source/drain openings with inner spacers.

10. The method of claim 1, further comprising, after forming the source/drain regions and before removing the dummy gate structure, forming an interlayer dielectric (ILD) layer over the source/drain regions around the dummy gate structure.

11. A method of forming a semiconductor device, the method comprising:
forming a fin structure that protrudes above shallow trench isolation (STI) regions, wherein the STI regions are over a substrate and on opposing sides of the fin structure, wherein the fin structure comprises a fin and a layer stack over the fin, wherein the layer stack comprises alternating layers of a first semiconductor material and a second semiconductor material;
forming an STI protection structure that extends along upper surfaces of the STI regions and along sidewalls of the fin, wherein the STI protection structure comprises a hard mask layer and a liner layer along sidewalls of the hard mask layer and along a bottom surface of the hard mask layer facing the substrate;
forming a dummy gate structure over the fin structure and the STI protection structure;
forming source/drain openings in the fin structure on opposing sides of the dummy gate structure;
after forming the source/drain openings, replacing the first semiconductor material disposed under the dummy gate structure with a sacrificial material;
after the replacing, forming source/drain regions in the source/drain openings;
forming an interlayer dielectric (ILD) layer over the source/drain regions and around the dummy gate structure;
removing the dummy gate structure to form a gate trench in the ILD layer, wherein the gate trench exposes the sacrificial material and a first portion of the second semiconductor material;
selectively removing the sacrificial material, wherein after the selectively removing, the first portion of the second semiconductor material forms nanostructures; and
forming a replacement gate structure around the nanostructures.

12. The method of claim 11, wherein the liner layer is formed of a first dielectric material, and the hard mask layer is formed of a second dielectric material different from the first dielectric material.

13. The method of claim 12, wherein the second dielectric material is more etch resistant to an etchant used in the selective removal of the sacrificial material than the first dielectric material.

14. The method of claim 12, wherein forming the STI protection structure comprises:
forming the first dielectric material over the upper surfaces of the STI regions, along sidewalls of the fin structure, and along a top surface of the fin structure, wherein the first dielectric material is formed to have a substantially uniform thickness;
forming the second dielectric material over the first dielectric material, wherein the second dielectric material is formed to have a non-uniform thickness; and
removing the first dielectric material and the second dielectric material from the top surface of the fin structure and from upper portions of the sidewalls of the fin structure, wherein after the removing, a remaining portion of the first dielectric material and a remaining portion of the second dielectric material form the liner layer and the hard mask layer of the STI protection structure, respectively.

15. The method of claim 14, wherein the second dielectric material is formed to have a first thickness in a first portion of the second dielectric material and have a second thickness in a second portion of the second dielectric material, wherein the first portion of the second dielectric material is along the upper surfaces of the STI regions, and the second portion of the second dielectric material is along the sidewalls of the fin structure, wherein the first thickness is larger than the second thickness.

16. The method of claim 14, wherein forming the second dielectric material comprises performing a plurality of deposition cycles, wherein each of the plurality of deposition cycles comprises a plurality of processing steps and is performed by:
depositing a silicon layer using a first plasma process, wherein the silicon layer has a first portion along the upper surfaces of the STI regions and has a second portion along the sidewalls of the fin structure;
increasing a ratio between a thickness of the first portion of the silicon layer and a thickness of the second portion of the silicon layer by performing a second plasma process; and
after performing the second plasma process, converting the silicon layer into a nitride layer by performing a third plasma process.

17. The method of claim 16, wherein the first plasma process is performed using a first gas source comprising a silicon-containing precursor and hydrogen gas, the second plasma process is performed using a second gas source comprising hydrogen gas, and the third plasma process is performed using a third gas source comprising nitrogen gas.

18. A semiconductor device comprising:
a substrate;
a fin protruding above the substrate;
shallow trench isolation (STI) regions on opposing sides of the fin;
source/drain regions over the fin;
channel layers over the fin and between the source/drain regions;
a gate structure between the source/drain regions and around the channel layers; and
an STI protection structure between the gate structure and the STI regions, wherein the STI protection structure comprises a liner layer and a hard mask layer over the liner layer, wherein the STI protection structure extends along upper surfaces of the STI regions and sidewalls of the fin.

19. The semiconductor device of claim 18, wherein the liner layer comprises a first dielectric material, and the hard mask layer comprises a second dielectric material different from the first dielectric material.

20. The semiconductor device of claim 18, wherein the liner layer extends along sidewalls of the hard mask layer and a bottom surface of the hard mask layer.
